(19) United States
(12) Patent Application Publication
(10) Pub. No.: US 2026/0096484 A1
(43) Pub. Date: Apr. 2, 2026

(54) SEMICONDUCTOR PACKAGE AND MANUFACTURING METHOD THEREOF

(71) Applicant: Samsung Electronics Co., Ltd., Suwon-si (KR)

(72) Inventors: Suk Won JANG, Suwon-si (KR); Jae Choon KIM, Suwon-si (KR)

(73) Assignee: Samsung Electronics Co., Ltd., Suwon-si (KR)

(21) Appl. No.: 19/203,560

(22) Filed: May 9, 2025

(30) Foreign Application Priority Data
Oct. 2, 2024 (KR) 10-2024-0133996

(51) Int. Cl. H01L 25/18; H01L 21/56; H01L 21/683; H01L 23/00; H01L 23/29; H01L 23/31; H01L 23/367; H01L 23/498; H01L 23/538; H10B 80/00; H10D 80/30

(52) U.S. Cl. CPC H10W 90/00; H10B 80/00; H10D 80/30; H10W 40/228; H10W 70/611; H10W 70/65; H10W 74/40; H10W 90/401; H10P 72/74; H10W 74/016; H10W 74/141; H10W 90/724; H10W 90/794

(57) ABSTRACT

A semiconductor package that includes a first redistribution structure; a logic die on the first redistribution structure; a plurality of conductive posts on the first redistribution structure, the plurality of conductive posts being laterally next to the logic die; a second redistribution structure on the logic die and the plurality of conductive posts; and a memory package on the second redistribution structure. The memory package includes a plurality of first bumps; a plurality of second bumps laterally next to the plurality of first bumps; an interposer on the plurality of first bumps, the interposer defining a through opening through the interposer; a heat dissipating structure on the plurality of second bumps, the heat dissipating structure being in the through opening; and a memory structure on the interposer, the memory structure being laterally next to the heat dissipating structure.

### CROSS-REFERENCE TO RELATED APPLICATION

This application claims priority to and the benefit of Korean Patent Application No. 10-2024-0133996 filed in the Korean Intellectual Property Office on Oct. 2, 2024, the entire contents of which are incorporated herein by reference.

### BACKGROUND

The present disclosure relates to semiconductor packages and manufacturing methods thereof.

In accordance with demand in the semiconductor industry, semiconductor packages are becoming lighter, thinner, smaller, faster, and more functional. As semiconductor packages become lighter, thinner, smaller, faster, and more functional, the power per unit volume consumed by the semiconductor chip of the semiconductor packages increases, which increases the heat generated from the semiconductor chip. When the heat generated in the semiconductor chip is not released to the outside of the semiconductor package, the heat stays in the semiconductor package including the semiconductor chip, and a thermal stress difference occurs in a semiconductor package structure, which may cause warpage in the semiconductor package. When the heat generated by the semiconductor chip fails to be released to the outside of the semiconductor package, the temperature of the semiconductor package increases, which may affect an operating rate of the semiconductor chip, and may worsen product reliability.

To address such issues, a heat dissipating structure made of a metal material with high thermal conductivity may be used in the semiconductor packages. The heat dissipating structure may be attached to a heat generating structure in the semiconductor package by a thermal interface material (TIM). The thermal interface material (TIM) including conductive fillers has higher thermal conductivity than general adhesive members, and have lower thermal conductivity than metal materials. Therefore, in the process of transmitting heat to the heat dissipating structure from a heat generating structure through the thermal interface material (TIM), the heat may remain in the thermal interface material (TIM), which may increase thermal resistance, and this may cause the heat dissipating characteristics of the semiconductor package to deteriorate.

The process of attaching the thermal interface material (TIM) to the heat generating structure and attaching the heat dissipating structure to the thermal interface material (TIM) must be performed separately from a flip chip bonding process for mounting the semiconductor chip, so total time and cost to manufacture the semiconductor package increase when the semiconductor package to which the thermal interface material (TIM) and the heat dissipating structure are applied is manufactured.

### SUMMARY

Some example embodiments are directed to a package on package (PoP) including a memory package including an interposer, a memory structure on the interposer, and a heat dissipating structure on the interposer, are integrally formed and disposed on a back-side redistribution structure.

The heat dissipating structure may be physically and thermally connected to the interposer or the back-side redistribution structure by dummy connection members.

Some example embodiments of the present disclosure provide a semiconductor package that includes a first redistribution structure; a logic die on the first redistribution structure; a plurality of conductive posts on the first redistribution structure, the plurality of conductive posts being laterally next to the logic die; a second redistribution structure on the logic die and the plurality of conductive posts; and a memory package on the second redistribution structure. The memory package includes a plurality of first bumps; a plurality of second bumps laterally next to the plurality of first bumps; an interposer on the plurality of first bumps, the interposer defining a through opening through the interposer; a heat dissipating structure on the plurality of second bumps, the heat dissipating structure being in the through opening; and a memory structure on the interposer, the memory structure being laterally next to the heat dissipating structure.

Some example embodiments of the present disclosure further provide a semiconductor package that includes a first redistribution structure; a logic die on the first redistribution structure; a plurality of conductive posts on the first redistribution structure, the plurality of conductive posts being laterally next to the logic die; a second redistribution structure on the logic die and the plurality of conductive posts; and a memory package on the second redistribution structure. The memory package includes a plurality of bumps; an interposer on the plurality of bumps; a heat dissipating structure on the interposer; and a memory structure on the interposer, the memory structure being laterally next to the heat dissipating structure.

Some example embodiments of the present disclosure still further provide a semiconductor package that includes a front-side redistribution structure; a logic die on the front-side redistribution structure; conductive posts on the front-side redistribution structure, the conductive posts being laterally next to the logic die; a first molding material covering the logic die and the conductive posts on the front-side redistribution structure; a back-side redistribution structure on the conductive posts and the first molding material; a memory package on the back-side redistribution structure; and a second molding material covering the memory package on the back-side redistribution structure. The memory package includes an interposer defining a through opening through the interposer; a plurality of first bumps between the back-side redistribution structure and the interposer; a heat dissipating structure in the through opening; a plurality of second bumps between the back-side redistribution structure and the heat dissipating structure; a memory structure on the interposer, the memory structure being laterally next to the heat dissipating structure; and a third molding material covering the memory structure on the interposer.

Some example embodiments of the present disclosure provide a method of manufacturing a semiconductor package that includes forming a plurality of conductive posts on a first redistribution structure; attaching a logic die on the first redistribution structure, the logic die being laterally next to the plurality of conductive posts; forming a second redistribution structure on the logic die and the plurality of conductive posts, the second redistribution structure including a plurality of wire patterns and a plurality of dummy wire patterns laterally next to the plurality of wire patterns; and attaching a memory package on the second redistribution structure, the memory package including an interposer, a plurality of memory structures on the interposer, and a heat dissipation structure laterally next to the plurality of memory structures. The attaching the memory package on the second redistribution structure includes electrically connecting the plurality of memory structures to the plurality of conductive posts through signal routing paths of the interposer and the plurality of wire patterns; and thermally connecting the heat dissipation structure to the logic die through the plurality of dummy wire patterns. The plurality of dummy wire patterns are electrically disconnected from the logic die.

In some example embodiments of the method of manufacturing the semiconductor package, the interposer defines an opening therethrough, and the attaching the memory package on the second redistribution structure includes attaching the heat dissipation structure to the second redistribution structure in the opening.

In some example embodiments of the method of manufacturing the semiconductor package, the heat dissipation structure includes a body part and an extension part extending laterally from the body part, and the method of manufacturing the semiconductor package further comprises providing the body part in the opening and attaching the extension part of the heat dissipation structure to an upper surface of the interposer.

In some example embodiments of the method of manufacturing the semiconductor package, the method further includes attaching the extension part of the heat dissipation structure to the interposer with an adhesive member, the adhesive member including a thermal interface material.

In some example embodiments of the method of manufacturing the semiconductor package, the thermally connecting the heat dissipation structure to the logic die further includes thermally connecting the plurality of dummy wiring patterns to the heat dissipation structure through thermal conduction paths of the interposer, the thermal conduction paths being laterally next to the signal routing paths.

In some example embodiments of the method of manufacturing the semiconductor package, the attaching the memory package on the second redistribution structure includes overlapping a footprint of the heat dissipation structure with a footprint of the logic die.

In some example embodiments of the method of manufacturing the semiconductor package, the attaching the memory package includes a flip chip bonding process.

Some example embodiments of the present disclosure further provide a method of manufacturing a semiconductor package that includes forming a plurality of conductive posts on a first redistribution structure; attaching a logic die on the first redistribution structure, the logic die being laterally next to the plurality of conductive posts; forming a second redistribution structure on the logic die and the plurality of conductive posts, the second redistribution structure including a plurality of wire patterns and a plurality of dummy wire patterns laterally next to the plurality of wire patterns; and attaching a memory package on the second redistribution structure. Manufacturing the memory package includes attaching memory structures to a carrier; forming a first molding layer on the carrier, the first molding layer surrounding the memory structures; forming an interposer on the memory structures; forming an opening through the interposer and the first molding layer to expose the carrier, the opening being between the memory structures; attaching a heat dissipation structure on the carrier and within the opening; forming a second molding layer surrounding the heat dissipation structure within the opening, and removing the carrier to provide the memory package. The attaching the memory package on the second redistribution structure includes electrically connecting the memory structures to the plurality of conductive posts through signal routing paths of the interposer and the plurality of dummy wire patterns, and thermally connecting the heat dissipation structure to the logic die through the plurality of dummy wire patterns.

In some example embodiments of the method of manufacturing the semiconductor package, the heat dissipation structure includes a body part and an extension part extending laterally from the body part, and the manufacturing the memory package further includes providing the body part in the opening and attaching the extension part of the heat dissipation structure to an upper surface of the interposer.

In some example embodiments the method of manufacturing the semiconductor package further includes attaching the extension part of the heat dissipation structure to the interposer with an adhesive member, the adhesive member comprising a thermal interface material.

In some example embodiments of the method of manufacturing the semiconductor package, the attaching the memory package on the second redistribution structure includes overlapping a footprint of the heat dissipation structure with a footprint of the logic die.

In some example embodiments of the method of manufacturing the semiconductor package, the attaching the memory package includes a flip chip bonding process.

Some example embodiments of the present disclosure further provide a method of manufacturing a semiconductor package that includes forming a plurality of conductive posts on a first redistribution structure; attaching a logic die on the first redistribution structure, the logic die being laterally next to the plurality of conductive posts; forming a second redistribution structure on the logic die and the plurality of conductive posts, the second redistribution structure including a plurality of wire patterns and a plurality of dummy wire patterns laterally next to the plurality of wire patterns; and attaching a memory package on the second redistribution structure. Manufacturing the memory package includes forming an interposer on a carrier; mounting memory structures on the interposer; mounting a heat dissipation structure on the interposer, the heat dissipation structure being between the memory structures; forming a first molding layer on the carrier, the first molding layer surrounding the memory structures and the heat dissipation structure; forming an interposer on the memory structures; and removing the carrier to provide the memory package. The attaching the memory package on the second redistribution structure includes electrically connecting the memory structures to the plurality of conductive posts through signal routing paths of the interposer and the plurality of wire patterns, and thermally connecting the heat dissipation structure to the logic die through thermal conduction paths of the interposer and the plurality of dummy wire patterns.

In some example embodiments of the method of manufacturing the semiconductor package, the attaching the memory package on the second redistribution structure includes overlapping a footprint of the heat dissipation structure with a footprint of the logic die.

In some example embodiments of the method of manufacturing the semiconductor package, the attaching the memory package includes a flip chip bonding process.

The integral memory package including a memory structure and a heat dissipating structure according to some example embodiments may be manufactured considering the size of the semiconductor package, the structure of the semiconductor package, and the hot spot region in the semiconductor package.

The integral memory package may be mounted on the back-side redistribution structure of the package on package (PoP) by performing a flip chip process. As the integral memory package may be mounted on the back-side redistribution structure by one process, the time and cost of manufacturing the semiconductor package may be reduced, compared to the case of respectively bonding the memory structure and the heat dissipating structure on the back-side redistribution structure.

The heat dissipating structure may be physically and thermally connected to the interposer or the back-side redistribution structure by the dummy connection members, thereby increasing the heat dissipating characteristic of the semiconductor package.

### BRIEF DESCRIPTION OF THE DRAWINGS

FIG. 1 shows a cross-sectional view of a semiconductor package according to some example embodiments.

FIG. 2 shows a top plan view of an upper surface of a semiconductor package of FIG. 1.

FIG. 3 shows a cross-sectional view of a semiconductor package according to some example embodiments.

FIG. 4 shows a top plan view of an upper surface of a semiconductor package of FIG. 3.

FIGS. 5, 6, 7, 8, 9, 10, 11, 12 and 13 show cross-sectional views of a method of manufacturing a memory package according to some example embodiments of FIG. 1.

FIGS. 14, 15, 16, 17, 18, 19, 20 and 21 show cross-sectional views of a method of manufacturing a semiconductor package according to some example embodiments of FIG. 1.

FIG. 22 shows a cross-sectional view of a semiconductor package according to some example embodiments.

FIG. 23 shows a top plan view of an upper surface of a semiconductor package of FIG. 22.

FIG. 24 shows a cross-sectional view of a semiconductor package according to some example embodiments.

FIG. 25 shows a top plan view of an upper surface of a semiconductor package of FIG. 24.

FIGS. 26, 27, 28, 29, 30, 31, 32, 33 and 34 show cross-sectional views of a method of manufacturing a memory package according to some example embodiments of FIG. 22.

FIG. 35 shows a cross-sectional view of a semiconductor package according to some example embodiments.

FIG. 36 shows a top plan view of an upper surface of a semiconductor package of FIG. 35.

FIG. 37 shows a cross-sectional view of a semiconductor package according to some example embodiments.

FIG. 38 shows a top plan view of an upper surface of a semiconductor package of FIG. 37.

FIGS. 39, 40, 41, 42, 43, 44 and 45 show cross-sectional views of a method of manufacturing a memory package according to some example embodiments of FIG. 35.

### DETAILED DESCRIPTION

The present disclosure will be described more fully hereinafter with reference to the accompanying drawings, in which some example embodiments of the disclosure are shown. As those skilled in the art would realize, the described some example embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The size and thickness of each configuration shown in the drawings are arbitrarily shown for better understanding and ease of description, but the present disclosure is not limited thereto.

Throughout this specification and the claims that follow, when it is described that an element is “coupled” to another element, the element may be “directly coupled” to the other element or “indirectly coupled” to the other element through a third element. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means disposed on or below the object portion, and does not necessarily mean disposed on the upper side of the object portion based on a gravitational direction.

The phrase “in a plan view” means viewing an object portion from the top, and the phrase “in a cross-sectional view” means viewing a cross-section of which the object portion is vertically cut from the side.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Semiconductor packages 100, 100A, 100B, 100C, 100D, 100E, and 100F according to some example embodiments, and manufacturing methods thereof, will now be described with reference to accompanying drawings.

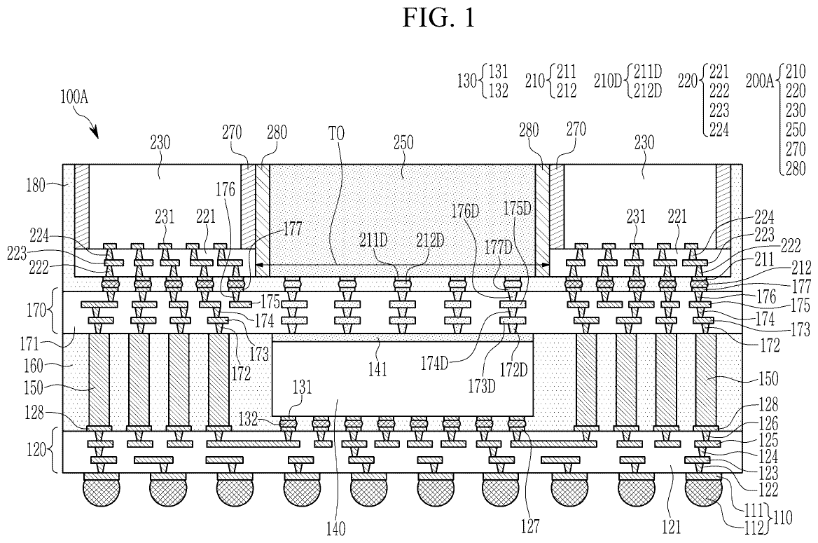

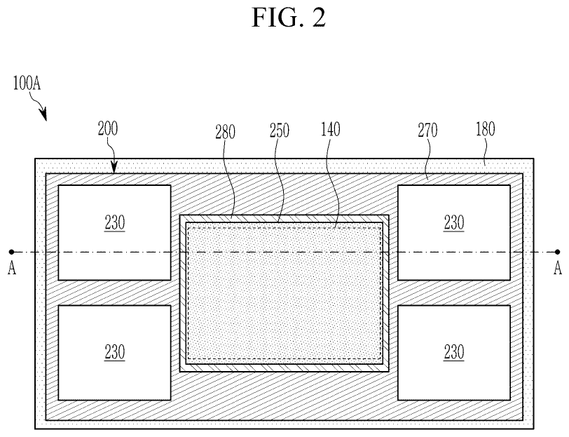

FIG. 1 shows a cross-sectional view of a semiconductor package 100A according to some example embodiments. FIG. 1 shows a cross-sectional view of a semiconductor package 100A with respect to a line A-A according to some example embodiments of FIG. 2.

Referring to FIG. 1, the semiconductor package 100A may include an external connection structure 110, a front-side redistribution structure (or first redistribution structure) 120, connection members 130, a logic die 140, a heat dissipating member 141, conductive posts 150, a first molding material 160, a back-side redistribution structure (or second redistribution structure) 170, a memory package 200A, and a second molding material 180. In some example embodiments, the semiconductor package 100A may include a package on package (PoP). In some example embodiments, the semiconductor package 100A may be manufactured based on the fan out wafer level package (FOWLP) technique or the fan out panel level package (FOPLP) technique.

The external connection structure 110 may be disposed on a bottom surface of the first redistribution structure 120. The external connection structure 110 may include conductive pads 111 and external connection members 112. Each of the conductive pads 111 may electrically connect a corresponding first redistribution via 122 among the first redistribution vias 122 in the first redistribution structure 120 to a corresponding external connection member 112 among the external connection members 112. The external connection members 112 may electrically connect the semiconductor package 100A to an external device (not shown).

The first redistribution structure 120 may be disposed on the external connection structure 110. The first redistribution structure 120 may include a first dielectric 121, first redistribution vias 122, first redistribution lines 123, second redistribution vias 124, second redistribution lines 125, third redistribution vias 126 disposed in the first dielectric 121, and first bonding pads 127 and second bonding pads 128 disposed on the first dielectric 121. In some example embodiments, the first redistribution structure 120 may include a greater/lesser number of redistribution lines, redistribution vias, and bonding pads.

The first dielectric 121 may protect and insulate the first redistribution vias 122, the first redistribution lines 123, the second redistribution vias 124, the second redistribution lines 125, and the third redistribution vias 126. The first bonding pads 127, the second bonding pads 128, and the first molding material 160 may be disposed on an upper surface of the first dielectric 121. The conductive pads 111 may be disposed on a bottom surface of the first dielectric 121.

The first redistribution vias 122, the first redistribution lines 123, the second redistribution vias 124, the second redistribution lines 125, and the third redistribution vias 126 may be sequentially disposed from the bottom, and may form signal, ground, and electric power routing paths. The first redistribution lines 123 and the second redistribution lines 125 may extend in a horizontal direction in the first dielectric 121. The first redistribution vias 122, the second redistribution vias 124, and the third redistribution vias 126 may extend in a vertical direction in the first dielectric 121.

Each of the first bonding pads 127 may be disposed between a corresponding third redistribution via 126 among the third redistribution vias 126 and a corresponding connection member 130 among the connection members 130. Each of the first bonding pads 127 may electrically connect a corresponding connection member 130 among the connection members 130 to a corresponding third redistribution via 126 among the third redistribution vias 126. Each of the second bonding pads 128 may be disposed between a corresponding third redistribution via 126 among the third redistribution vias 126 and a corresponding conductive post 150 among the conductive posts 150. Each of the second bonding pads 128 may electrically connect a corresponding conductive post 150 among the conductive posts 150 to a corresponding third redistribution via 126 among the third redistribution vias 126. Diameters of each of second bonding pads 128 in the horizontal direction may be greater than diameters of each of the first bonding pads 127 in the horizontal direction.

The connection members 130 may be disposed between the first redistribution structure 120 and the logic die 140. The connection members 130 may electrically connect the logic die 140 to the first redistribution structure 120. The connection members 130 may be disposed next to (e.g., laterally next to) conductive posts 150. In some example embodiments, the connection members 130 may be micro bumps. Each of the connection members 130 may include a pillar 131 and a solder 132. The pillar 131 may be disposed between the corresponding wire among the wires of the logic die 140 and the corresponding solder 132. The pillar 131 may electrically connect the corresponding wire among the wires of the logic die 140 to the corresponding solder 132. In some example embodiments, the pillar 131 may include at least one of copper, aluminum, silver, tin, gold, nickel, lead, titanium, and alloys thereof. The solder 132 may be disposed between the corresponding pillar 131 and the corresponding first bonding pad 127 among the first bonding pads 127. The solder 132 may electrically connect the corresponding pillar 131 to the corresponding first bonding pad 127 among the first bonding pads 127. In some example embodiments, the solder 132 may include at least one of tin, silver, lead, nickel, copper, and alloys thereof.

The logic die 140 may be disposed on the connection members 130. The logic die 140 may be disposed side by side the conductive posts 150. The logic die 140 may be disposed next to (e.g., laterally next to) the conductive posts 150. In some example embodiments, the logic die 140 may include a system on chip (SoC). In some example embodiments, the logic die 140 may include an application processor (AP). In some example embodiments, the logic die 140 may include at least one of a central processing unit (CPU), a graphic processing unit (GPU), a signal processor, a network processor, and a codec.

The heat dissipating member 141 may be disposed on the logic die 140. The heat dissipating member 141 may be inserted between the logic die 140 and the back-side redistribution structure 170 and may increase a thermal combination between the logic die 140 and the back-side redistribution structure 170. Heat generated by the logic die 140 may pass through the heat dissipating member 141 and may be transmitted to dummy wire patterns of the back-side redistribution structure 170. In some example embodiments, the heat dissipating member 141 may include a dummy structure made of a silicon material or a metal material. In some example embodiments, the heat dissipating member 141 may include thermal interface material (TIM). In some example embodiments, the heat dissipating member 141 may not be included in the semiconductor package 100A.

The conductive posts 150 may be disposed on the first redistribution structure 120. The conductive posts 150 may be disposed next the logic die 140. The conductive posts 150 may be disposed around the logic die 140. Each of the conductive posts 150 may be disposed between a corresponding second bonding pad 128 among the second bonding pads 128 in the first redistribution structure 120 and a corresponding fourth redistribution via among the fourth redistribution vias 172 in the back-side redistribution structure 170. Each of the conductive posts 150 may electrically connect a corresponding fourth redistribution via among the fourth redistribution vias 172 in the back-side redistribution structure 170 to a corresponding second bonding pad 128 among the second bonding pads 128 in the first redistribution structure 120. The conductive posts 150 may be disposed to pass through the first molding material 160. A lateral surface of the conductive posts 150 may be surrounded by the first molding material 160.

The first molding material 160 may cover the connection members 130, the logic die 140, the heat dissipating member 141, and the conductive posts 150 on the first redistribution structure 120. The first molding material 160 may protect the connection members 130, the logic die 140, the heat dissipating member 141, and the conductive posts 150 from external environments, and may obtain electrical or mechanical stability of the semiconductor package 100.

The back-side redistribution structure 170 may be disposed on the logic die 140, the heat dissipating member 141, the conductive posts 150, and the first molding material 160. The back-side redistribution structure 170 may include a second dielectric 171, wire patterns disposed in the second dielectric 171, dummy wire patterns in the second dielectric 171, third bonding pads 177 on the second dielectric 171, and dummy bonding pads 177D on the second dielectric 171. The wire patterns may include fourth redistribution vias 172, third redistribution lines 173, fifth redistribution vias 174, fourth redistribution lines 175, and sixth redistribution vias 176. The dummy wire patterns may include first dummy redistribution vias 172D, first dummy redistribution lines 173D, second dummy redistribution vias 174D, second dummy redistribution lines 175D, and third dummy redistribution vias 176D. In some example embodiments, the back-side redistribution structure 170 may include a greater/lesser number of the redistribution lines, redistribution vias, dummy redistribution lines, dummy redistribution vias, bonding pads, and dummy bonding pads.

The second dielectric 171 may protect and insulate the fourth redistribution vias 172, the third redistribution lines 173, the fifth redistribution vias 174, the fourth redistribution lines 175, the sixth redistribution vias 176, the first dummy redistribution vias 172D, the first dummy redistribution lines 173D, the second dummy redistribution vias 174D, the second dummy redistribution lines 175D, and the third dummy redistribution vias 176D. The third bonding pads 177, the dummy bonding pads 177D, and the second molding material 180 may be disposed on an upper surface of the second dielectric 171. The heat dissipating member 141, the conductive posts 150, and the first molding material 160 may be disposed on a bottom surface of the second dielectric 171.

The fourth redistribution vias 172, the third redistribution lines 173, the fifth redistribution vias 174, the fourth redistribution lines 175, and the sixth redistribution vias 176 may be sequentially disposed from the bottom, and may form signal, ground, and electric power routing paths. The third redistribution lines 173 and the fourth redistribution lines 175 may extend in the horizontal direction in the second dielectric 171. The fourth redistribution vias 172, the fifth redistribution vias 174, and the sixth redistribution vias 176 may extend in the vertical direction in the second dielectric 171.

The third bonding pads 177 may be disposed on the second dielectric 171. The third bonding pads 177 may be disposed next dummy bonding pads 177D. Each of the third bonding pads 177 may be disposed between a corresponding sixth redistribution via 176 among the sixth redistribution vias 176 and a corresponding first bump 210 among the first bumps 210. Each of the third bonding pads 177 may electrically connect a corresponding first bump 210 among the first bumps 210 to a corresponding sixth redistribution via 176 among the sixth redistribution vias 176.

The first dummy redistribution vias 172D, the first dummy redistribution lines 173D, the second dummy redistribution vias 174D, the second dummy redistribution lines 175D, and the third dummy redistribution vias 176D may be sequentially disposed from the bottom, and may form heat dissipating paths. The first dummy redistribution lines 173D and the second dummy redistribution lines 175D may extend in the horizontal direction in the second dielectric 171. The first dummy redistribution vias 172D, the second dummy redistribution vias 174D, and the third dummy redistribution vias 176D may extend in the vertical direction in the second dielectric 171.

The dummy bonding pads 177D may be disposed on the second dielectric 171. The dummy bonding pads 177D may be disposed next to the third bonding pads 177. Each of the dummy bonding pads 177D may be disposed between a corresponding third dummy redistribution via 176D among the third dummy redistribution vias 176D and a corresponding second bump 210D among the second bumps 210D. Each of the dummy bonding pads 177D may be thermally connected to a corresponding second bump 210D among the second bumps 210D, and a corresponding third dummy redistribution via 176D among the third dummy redistribution vias 176D.

The memory package 200A may be disposed on the back-side redistribution structure 170. The memory package 200A may be semiconductor package on which memory structures 230 and a heat dissipating structure 250 are integrally formed. The memory package 200A may include first bumps 210, second bumps 210D, an interposer 220, a memory structures 230, a heat dissipating structure 250, a third molding material 270, and a fourth molding material 280. In some example embodiments, the memory package 200A may include a system in package (SiP). In some example embodiments, the memory package 200A may be manufactured based on the fan out wafer level package (FOWLP) technology or the fan out panel level package (FOPLP) technology.

Each of the first bumps 210 may be disposed on a corresponding third bonding pad 177 among the third bonding pads 177, and may contact the corresponding third bonding pad 177. The first bumps 210 may be disposed on a bottom surface of the interposer 220. The first bumps 210 may be disposed next to the second bumps 210D. The first bumps 210 may be disposed side by side the second bumps 210D. The first bumps 210 may be disposed between the interposer 220 and the back-side redistribution structure 170 and may electrically connect them. In some example embodiments, the first bumps 210 may be micro bumps.

Each of the first bumps 210 may include a first pillar 211 and a first solder 212. The first pillar 211 may be disposed between a corresponding first via 222 among the first vias 222 of the interposer 220 and the corresponding first solder 212. The first pillar 211 may electrically connect the corresponding first via 222 among the first vias 222 of the interposer 220 to the corresponding first solder 212. In some example embodiments, the first pillar 211 may include at least one of copper, aluminum, silver, tin, gold, nickel, lead, titanium, and alloys thereof. The first solder 212 may be disposed between the corresponding first pillar 211 and the corresponding third bonding pad 177 among the third bonding pads 177. The first solder 212 may electrically connect the corresponding first pillar 211 to the corresponding third bonding pad 177 among the third bonding pads 177. In some example embodiments, the first solder 212 may include at least one of tin, silver, lead, nickel, copper, and alloys thereof.

Each of the second bumps 210D may be disposed on the corresponding dummy bonding pad 177D among the dummy bonding pads 177D, and may contact the corresponding dummy bonding pad 177D. The second bumps (or dummy bumps) 210D may be disposed on a bottom surface of the heat dissipating structure 250. The second bumps 210D may be disposed next the first bumps 210. The second bumps 210D may be disposed side by side the first bumps 210. The second bumps 210D may be disposed between the heat dissipating structure 250 and the back-side redistribution structure 170. The second bumps 210D may be thermally connected to the heat dissipating structure 250 and the back-side redistribution structure 170. The second bumps 210D may be dummy bumps. The second bumps 210D may be electrically separated (e.g., electrically disconnected) from the back-side redistribution structure 170. In some example embodiments, the second bumps 210D may be micro bumps.

Each of the second bumps 210D may include a second pillar 211D and a second solder 212D. The second pillar 211D may be disposed between the heat dissipating structure 250 and the corresponding second solder 212D. The second pillar 211D may be thermally connected to the heat dissipating structure 250 and the corresponding second solder 212D. In some example embodiments, the second pillar 211D may include a metal material with high thermal conductivity. In some example embodiments, the second pillar 211D may include at least one of copper, aluminum, silver, tin, gold, nickel, lead, titanium, and alloys thereof. The second solder 212D may be disposed between the corresponding second pillar 211D and the corresponding dummy bonding pad 177D among the dummy bonding pads 177D. The second solder 212D may be thermally connected to the corresponding second pillar 211D, and the corresponding dummy bonding pad 177D among the dummy bonding pads 177D. In some example embodiments, the second solder 212D may include at least one of tin, silver, lead, nickel, copper, and alloys thereof.

The interposer 220 may be disposed on the first bumps 210. The interposer 220 may include an interposer base 221, first vias 222, wiring lines 223, and second vias 224. The memory structures 230 and the third molding material 270 may be disposed on an upper surface of the interposer 220, and may support the memory structures 230. The interposer 220 may electrically connect the memory structures 230 and the first bumps 210. The interposer 220 may include a through opening TO, and the heat dissipating structure 250 may be disposed in the through opening TO. For example, the interposer 220 may define a through opening TO through the interposer 220. In some example embodiments, the interposer 220 may include a silicon interposer, a redistribution interposer, a glass interposer, or a composite interposer.

The interposer base 221 may protect and insulate the first vias 222, the wiring lines 223, and the second vias 224. In some example embodiments, the interposer base 221 may include a photo imageable dielectric (PID). In some example embodiments, the interposer base 221 may include a silicon material or a glass material.

The first vias 222, the wiring lines 223, and the second vias 224 may be sequentially disposed from the bottom, and may form signal, ground, and electric power routing paths. The wiring lines 223 may extend in the horizontal direction in the interposer base 221. The first vias 222 and the second vias 224 may extend in the vertical direction in the interposer base 221. The interposer 220 includes tow-layered vias in some example embodiments of FIG. 1, and in some example embodiments the interposer 220 may include a greater/lesser number of wire layers and vias. In some example embodiments, the first vias 222, the wiring lines 223, and the second vias 224 may respectively include at least one of copper, aluminum, silver, tin, gold, nickel, lead, titanium, and alloys thereof.

The memory structure 230 may be disposed on the interposer 220. The memory structure 230 may be disposed next to (e.g., laterally next to) the heat dissipating structure 250. There may be a plurality of memory structures 230. The memory structure 230 may contact the interposer 220 without a connection member and may be directly and electrically connected to the interposer. The memory structure 230 may include connection pads 231. Each of the connection pads 231 may contact a corresponding second via 224 among the second vias 224 of the interposer 220 and may be electrically connected to the same. In some example embodiments, the memory structure 230 may include a single chip such as a DRAM or multi-chip such as a high bandwidth memory (HBM).

The heat dissipating structure 250 may be disposed on the second bumps 210D. The heat dissipating structure 250 may be disposed in the through opening TO of the interposer 220. The heat dissipating structure 250 may be disposed next to the memory structure 230. The heat dissipating structure 250 may be thermally connected to the second bumps 210D. Heat generated by the logic die 140 may pass through the heat dissipating member 141, the first dummy redistribution vias 172D, the first dummy redistribution lines 173D, the second dummy redistribution vias 174D, the second dummy redistribution lines 175D, the third dummy redistribution vias 176D, the dummy bonding pads 177D, and the second bumps 210D and may be transmitted to the heat dissipating structure 250. The heat dissipating structure 250 may discharge the heat to the outside of the semiconductor package 100A. In some example embodiments, the heat dissipating structure 250 may include a heat slug, a heat sink, or a heat spreader. In some example embodiments, the heat dissipating structure 250 may include a conductive material with high thermal conductivity. In some example embodiments, the heat dissipating structure 250 may include at least one of copper, aluminum, silver, tin, gold, nickel, lead, titanium, and alloys thereof.

The third molding material 270 may cover the memory structures 230 on the interposer 220. An upper surface of the memory structure 230 may be exposed from the third molding material 270, and may have the same level as an upper surface of the third molding material 270. The fourth molding material 280 may cover an inside of the through opening TO, a space between the interposer 220 and the heat dissipating structure 250, and a space between the third molding material 270 and the heat dissipating structure 250. An upper surface of the heat dissipating structure 250 may be exposed from the fourth molding material 280, and may have the same level as an upper surface of the fourth molding material 280. In some example embodiments, the third molding material 270 and the fourth molding material 280 may respectively include a high dielectric constant molding material. The third molding material 270 and the fourth molding material 280 may protect the memory structure 230 and the heat dissipating structure 250 from the external environments, and may obtain electrical or mechanical stability of the semiconductor package 100A.

FIG. 2 shows a top plan view on an upper surface of a semiconductor package 100A of FIG. 1. Referring to FIG. 2, the second molding material 180, the memory structures 230, the heat dissipating structure 250, the third molding material 270, and the fourth molding material 280 are shown with solid lines, and the logic die 140 is shown with dotted lines.

Referring to FIG. 2, the second molding material 180 may surround the memory package 200A. The memory package 200A may include memory structures 230, a heat dissipating structure 250, a third molding material 270, and a fourth molding material 280. The memory package 200A may have a symmetric structure. The memory structures 230 may be disposed in parallel to the heat dissipating structure 250. The heat dissipating structure 250 may be disposed between the memory structures 230. The third molding material 270 may surround the memory structures 230 and the fourth molding material 280. The fourth molding material 280 may surround the heat dissipating structure 250.

A footprint of the heat dissipating structure 250 may overlap a footprint of the logic die 140. The footprint of the logic die 140 may be included in the footprint of the heat dissipating structure 250. Referring to FIG. 1 and FIG. 2, the footprints of the dummy wire patterns and the footprints of the dummy bonding pads 177D may overlap the footprint of the logic die 140. Heat generated by the logic die 140 may form a hot spot on an upper portion of the logic die 140, and the dummy wire patterns, the dummy bonding pads 177D, the second bumps 210D, and the heat dissipating structure 250 may be disposed on the hot spot. By this, heat generated by the logic die 140 may pass through the dummy wire patterns, the dummy bonding pads 177D, the second bumps 210D, and the heat dissipating structure 250 and may be more efficiently discharged to the outside of the semiconductor package 100A.

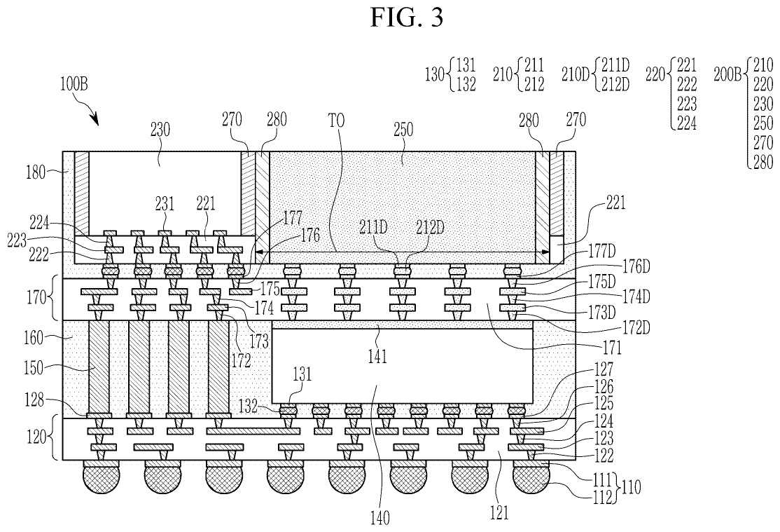

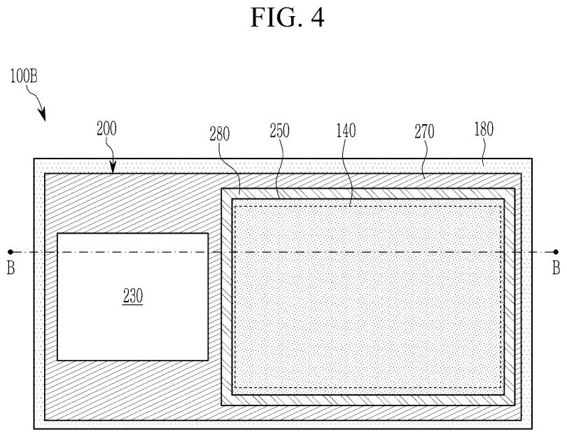

FIG. 3 shows a cross-sectional view of a semiconductor package 100B according to some example embodiments. FIG. 3 shows a cross-sectional view of a semiconductor package 100B with respect to a line B-B according to some example embodiments of FIG. 4. FIG. 4 shows a top plan view of an upper surface of a semiconductor package 100B of FIG. 3. Referring to FIG. 4, the second molding material 180, the memory structure 230, the heat dissipating structure 250, the third molding material 270, and the fourth molding material 280 are shown with solid lines, and the logic die 140 is shown with dotted lines.

Referring to FIG. 3 and FIG. 4, the semiconductor package 100B may include an asymmetric structure. The semiconductor package 100B may include conductive posts 150 disposed next to a lateral surface of the logic die 140. The memory package 200B may include the memory structure 230 disposed next a lateral surface of the heat dissipating structure 250. FIG. 4 shows one memory structure 230 disposed next to one lateral surface of the heat dissipating structure 250, and in some example embodiments the semiconductor package 100B may include a plurality of memory structures 230 disposed next one lateral surface of the heat dissipating structure 250.

The content described with respect to the semiconductor package 100A in FIG. 1 and FIG. 2 may be applied to structure not herein described with respect to the semiconductor package 100B according to some example embodiments in FIG. 3 and FIG. 4.

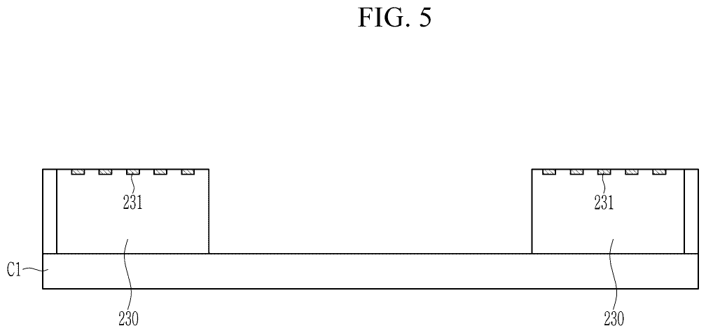

FIG. 5 to FIG. 13 show cross-sectional views of a method of manufacturing a memory package 200A according to some example embodiments of FIG. 1. FIG. 5 to FIG. 13 show cross-sectional views of a method of manufacturing the memory package 200A to which a chip first process is applied.

FIG. 5 shows a cross-sectional view of a process for attaching the memory structures 230 to a carrier C1.

Referring to FIG. 5, the memory structures 230 may be attached to the carrier C1. The carrier C1 may be provided. In some example embodiments, the carrier C1 may include a silicon-based material such as glass or silicon oxide, other materials such as an organic material or aluminum oxide, or arbitrary combinations of the materials. The memory structures 230 may be attached to the carrier C1 so that an opposite surface to the surface on which the connection pads 231 are disposed may contact the carrier C1. In some example embodiments, the memory structures 230 may be attached to the carrier C1 by a die attach film (not shown).

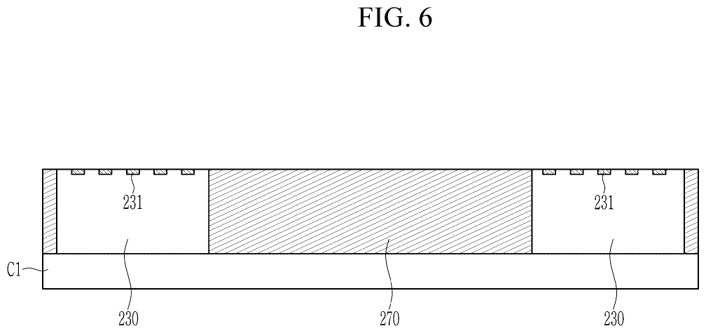

FIG. 6 shows a cross-sectional view of a process for molding the memory structures 230 on the carrier C1.

Referring to FIG. 6, the memory structures 230 may be covered with the third molding material 270 on the carrier C1. In some example embodiments, the molding process using the third molding material 270 may include a compression molding process or a transfer molding process. In some example embodiments, the third molding material 270 may include an epoxy molding compound (EMC). A chemical mechanical polishing (CMP) process may be performed to adjust a level of the upper surface of the third molding material 270, thereby planarizing the upper surface of the third molding material 270. When the chemical mechanical polishing (CMP) process is performed, the connection pads 231 may be exposed.

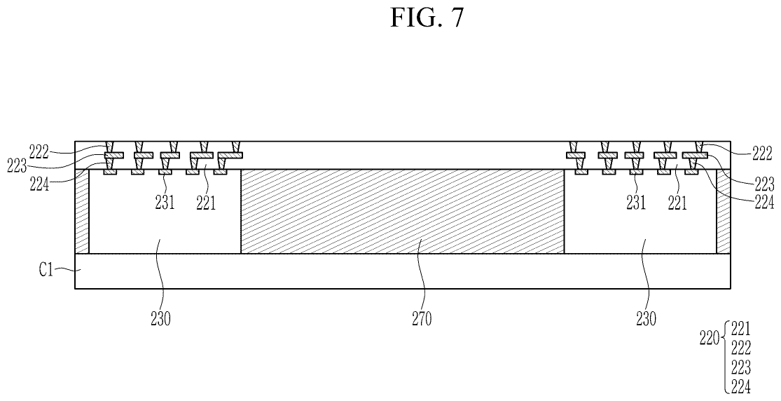

FIG. 7 shows a cross-sectional view for forming an interposer 220 on the memory structures 230 and the third molding material 270. FIG. 7 shows some example embodiments in which the interposer 220 is the redistribution interposer 220. When the interposer 220 is a silicon interposer, a glass interposer, or a composite interposer, the interposer 220 manufactured in advance may be bonded on the memory structures 230.

Referring to FIG. 7, the interposer 220 may be formed on the memory structures 230 and the third molding material 270. A dielectric may be formed as a film on the memory structures 230 and the third molding material 270, the dielectric may be selectively etched to form openings and fill the openings with a conductive material so that the second vias 224, the wiring lines 223, and the first vias 222 may be sequentially formed from the bottom. As the first vias 222 and the second vias 224 are formed later by the chip first process, the first vias 222 and the second vias 224 may respectively increase their widths in the horizontal direction when proceeding to the upper portion from the lower portion. Regarding the semiconductor package 100A that is the final product, first vias 222 and second vias 224 may respectively reduce their widths in the horizontal direction when proceeding to the upper portion from the lower portion. In some example embodiments, the dielectric may be formed into a film by performing a spin coating process. In some example embodiments, the dielectric may include a photo imageable dielectric (PID) used in the redistribution layer process. In some example embodiments, the photo imageable dielectric (PID) may include polyimide-based photoactive polymer, novolak-based photoactive polymer, polybenzoxazole, silicon-based polymer, acrylate-based polymer, or epoxy-based polymer. In some example embodiments, as the photoresist process and the etching process are performed, the dielectric may be etched, and the openings may be formed in the dielectric. In some example embodiments, the first vias 222, the wiring lines 223, and the second vias 224 may be formed by performing a sputtering process, or may be formed by forming a seed metal layer and performing the electrolytic plating process. In some example embodiments, the first vias 222, the wiring lines 223, and the second vias 224 may include at least one of copper, aluminum, tungsten, nickel, gold, tin, titanium, and alloys thereof, respectively.

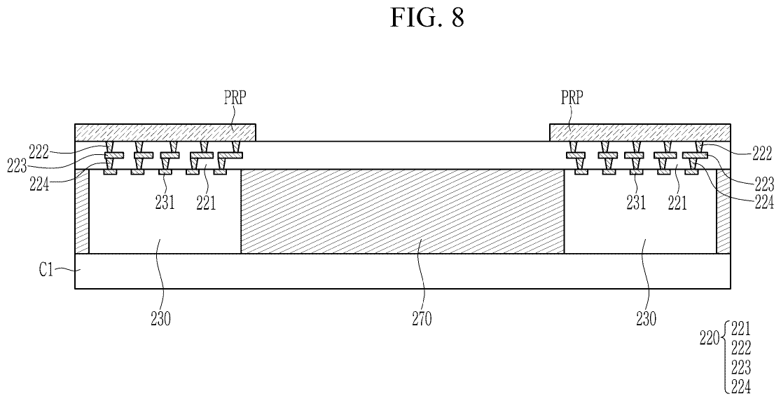

FIG. 8 shows a cross-sectional view of a process for forming a photoresist pattern PRP on the interposer base 221.

Referring to FIG. 8, photoresist may be formed as a film on the interposer base 221. In some example embodiments, the photoresist may be formed as a film by performing the spin coating process. In some example embodiments, the photoresist may include an organic polymer resin including a photoactive material. The photoresist may be exposed and developed to form the photoresist pattern PRP.

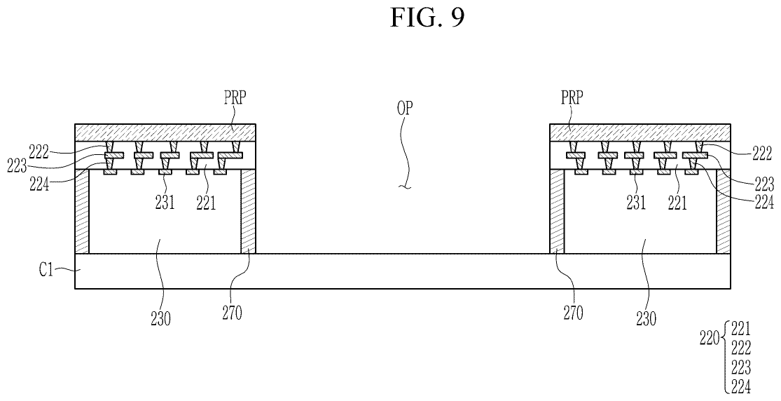

FIG. 9 shows a cross-sectional view of a process for forming an opening OP in the interposer base 221 and the third molding material 270.

Referring to FIG. 9, the interposer base 221 exposed from the photoresist pattern PRP may be etched and the third molding material 270 may be etched to form the opening OP. The carrier C1 may be exposed through the opening OP. In some example embodiments, the process for etching the interposer base 221 and the third molding material 270 may be performed by dry etching.

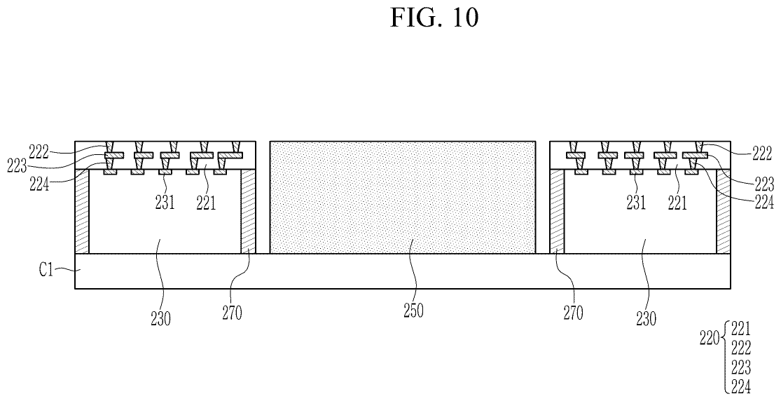

FIG. 10 shows a cross-sectional view of a process for attaching the heat dissipating structure 250 to the carrier C1 in the opening OP.

Referring to FIG. 10, the heat dissipating structure 250 may be attached to the carrier C1 in the opening OP. In some example embodiments, the heat dissipating structure 250 may be attached to the carrier C1 by a die attach film (not shown).

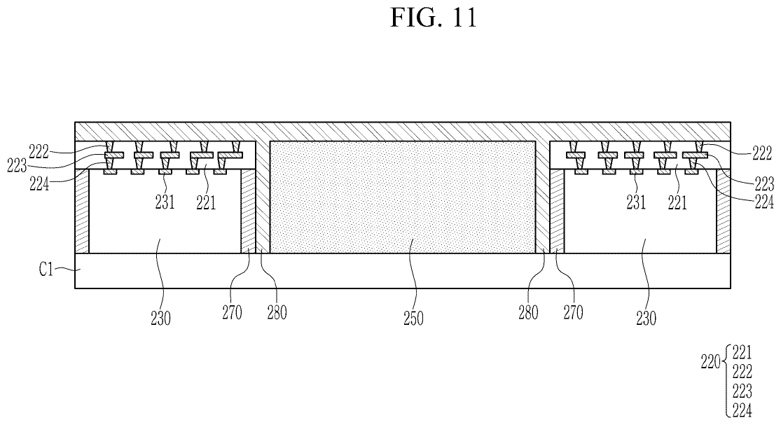

FIG. 11 shows a cross-sectional view for molding the heat dissipating structure 250 in the opening OP on the carrier C1.

Referring to FIG. 11, the heat dissipating structure 250 in the through opening TO (e.g., see FIG. 1) may be covered with the fourth molding material 280 on the carrier C1. In some example embodiments, the molding process with the fourth molding material 280 may include a compression molding or a transfer molding process. In some example embodiments, the fourth molding material 280 may include the epoxy molding compound (EMC).

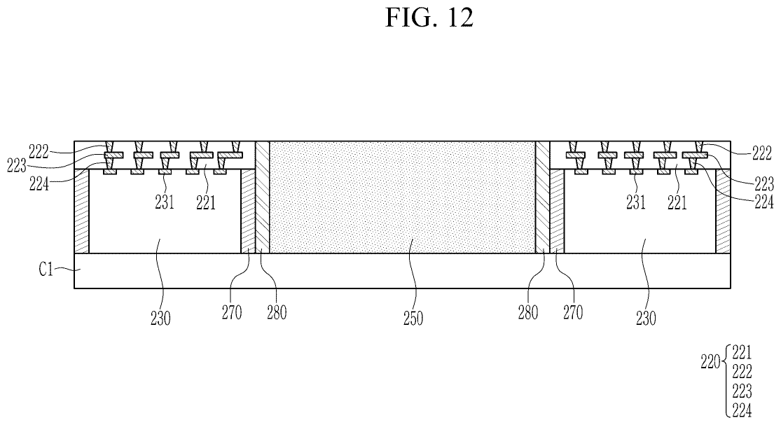

FIG. 12 shows a cross-sectional view of a process for planarizing the fourth molding material 280.

Referring to FIG. 12, a chemical mechanical polishing (CMP) may be performed on the fourth molding material 280. When the chemical mechanical polishing (CMP) process is performed, the first vias 222 of the interposer 220 and the heat dissipating structure 250 may be exposed.

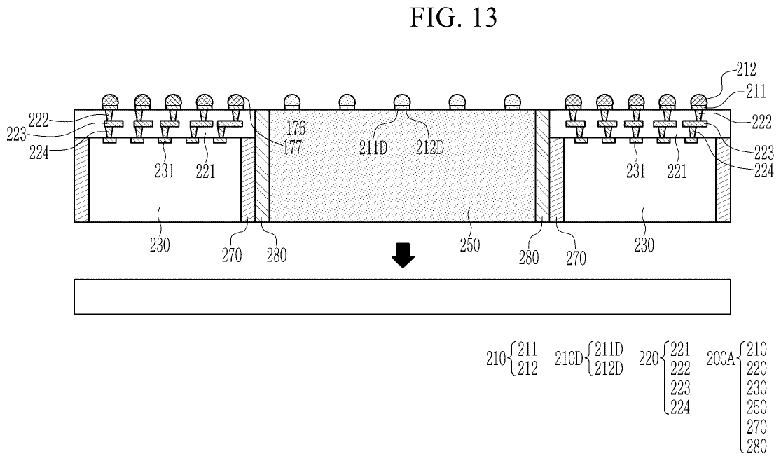

FIG. 13 shows a cross-sectional view of forming first bumps 210 on the interposer 220 and forming second bumps 210D on the heat dissipating structure 250.

Referring to FIG. 13, the first bumps 210 may be formed on the interposer 220, and the second bumps 210D may be formed in the heat dissipating structure 250. A first pillar 211 may be formed on each of the first vias 222 of the interposer 220, and a second pillar 211D may be formed on the heat dissipating structure 250. In some example embodiments, the first pillar 211 and the second pillar 211D may respectively include at least one of copper, nickel, zinc, gold, silver, platinum, palladium, chromium, titanium, and alloys thereof. In some example embodiments, the first pillar 211 and the second pillar 211D may be formed by performing a sputtering process, or may be formed by forming a seed metal layer and performing the electrolytic plating process. A first solder 212 may be formed on the first pillar 211, and a second solder 212D may be formed on the second pillar 211D. In some example embodiments, the first solder 212 and the second solder 212D may respectively include at least one of tin, silver, lead, nickel, copper, and alloys thereof. The carrier C1 may be removed from the memory structure 230, the heat dissipating structure 250, the third molding material 270, and the fourth molding material 280.

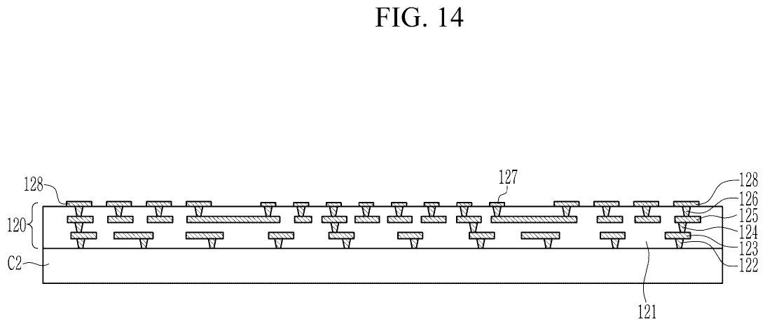

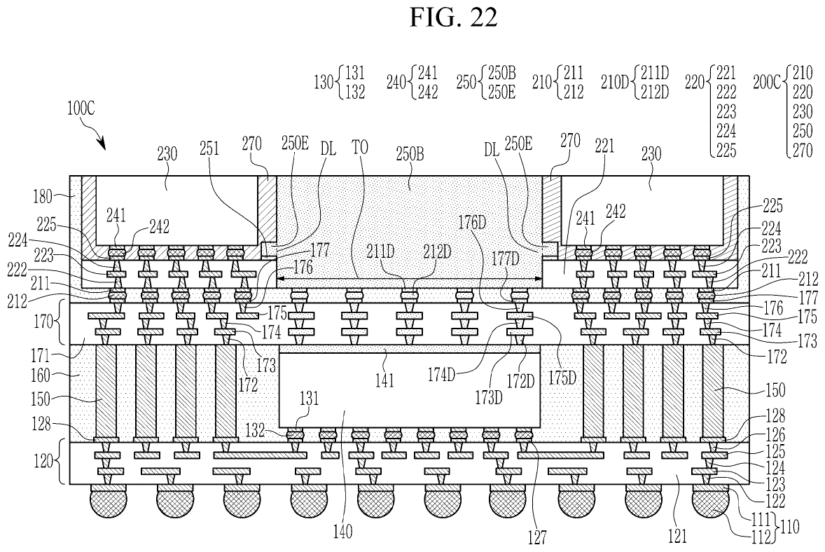

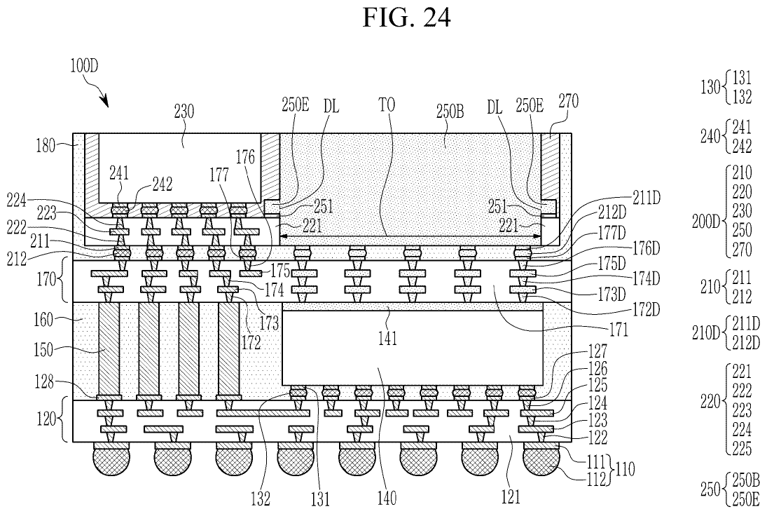

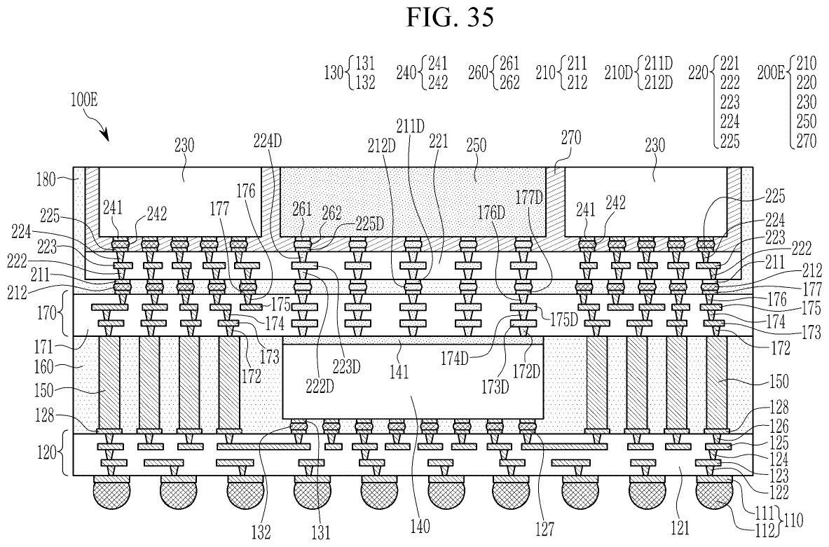

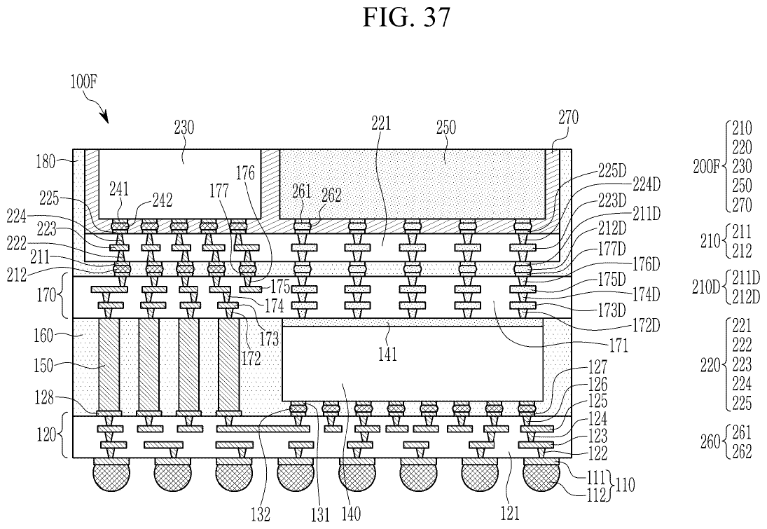

FIG. 14 to FIG. 21 show cross-sectional views of a method for manufacturing a semiconductor package 100A according to some example embodiments of FIG. 1. The method for manufacturing a semiconductor package 100A according to some example embodiments of FIG. 1 of FIG. 14 to FIG. 21 may be applied to the method for manufacturing a semiconductor package 100B according to some example embodiments of FIG. 3, a method for manufacturing a semiconductor package 100C according to some example embodiments of FIG. 22, a method for manufacturing a semiconductor package 100D according to some example embodiments of FIG. 24, a method for manufacturing a semiconductor package 100E according to some example embodiments of FIG. 35, and a method for manufacturing a semiconductor package 100F according to some example embodiments of FIG. 37.

FIG. 14 shows a cross-sectional view of a process for forming a first redistribution structure 120 on a carrier C2.

Referring to FIG. 14, a first redistribution structure 120 may be formed on the carrier C2. In some example embodiments, the carrier C2 may include a silicon-based material such as glass or silicon oxide, other materials such as an organic material or aluminum oxide, or arbitrary combinations of the materials. A first dielectric 121 may be formed on the carrier C2, the first dielectric 121 may be selectively etched to form openings, and the openings are filled with a conductive material so that the first redistribution vias 122, the first redistribution lines 123, the second redistribution vias 124, the second redistribution lines 125, and the third redistribution vias 126 may be sequentially formed from the bottom. When the third redistribution vias 126 is formed, photoresist may be additionally deposited on the third redistribution vias 126 and the first dielectric 121, the photoresist may be selectively exposed and developed to form a photoresist pattern including openings, and the openings may be filled with a conductive material to form the first bonding pads 127 and the second bonding pads 128.

In some example embodiments, the first dielectric 121 may be made into a film by performing the spin coating process. In some example embodiments, the first dielectric 121 may include the photo imageable dielectric (PID) used in the redistribution layer process. In some example embodiments, the photo imageable dielectric (PID) may include polyimide-based photoactive polymer, novolak-based photoactive polymer, polybenzoxazole, silicon-based polymer, acrylate-based polymer, or epoxy-based polymer. In some example embodiments, as the photoresist process and the etching process are performed, the first dielectric 121 may be etched, and openings may be formed in the first dielectric 121. In some example embodiments, the first redistribution vias 122, the first redistribution lines 123, the second redistribution vias 124, the second redistribution lines 125, the third redistribution vias 126, the first bonding pads 127, and the second bonding pads 128 may be formed by performing the sputtering process, or may be formed by forming a seed metal layer and performing the electrolytic plating process. In some example embodiments, the first redistribution vias 122, the first redistribution lines 123, the second redistribution vias 124, the second redistribution lines 125, the third redistribution vias 126, the first bonding pads 127, and the second bonding pads 128 may include at least one of copper, aluminum, tungsten, nickel, gold, tin, titanium, and alloys thereof, respectively.

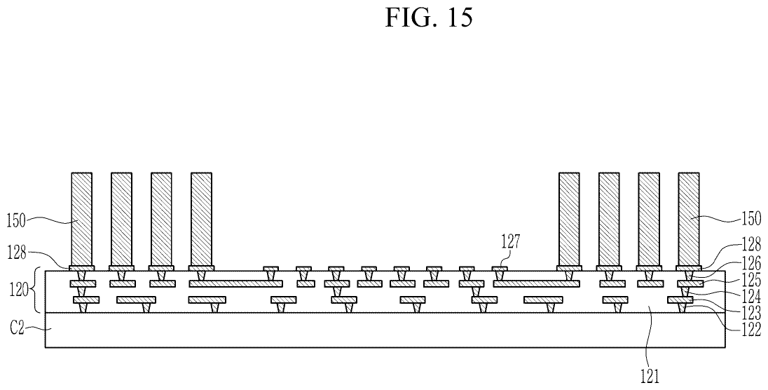

FIG. 15 shows a cross-sectional view of a process for forming conductive posts 150 on the second bonding pads 128.

Referring to FIG. 15, the conductive posts 150 may be formed on the second bonding pads 128 of the first redistribution structure 120. In some example embodiments, the conductive posts 150 may be formed by performing the sputtering process, or may be formed by forming a seed metal layer and performing the electrolytic plating process. In some example embodiments, the conductive posts 150 may include at least one of copper, aluminum, tungsten, nickel, gold, silver, chromium, antimony, tin, titanium, and alloys thereof.

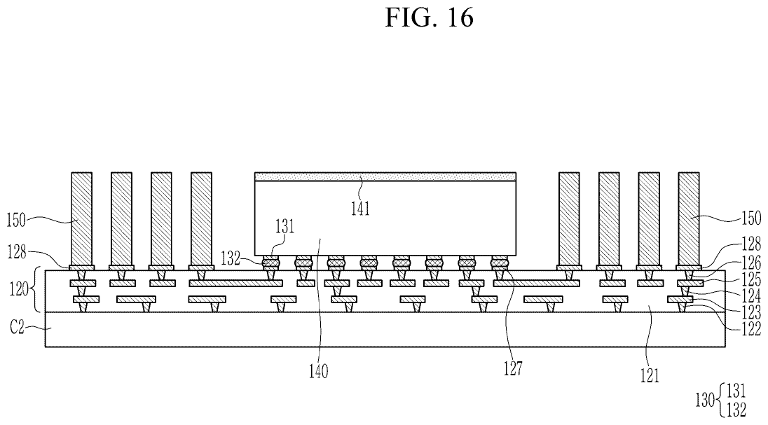

FIG. 16 shows a cross-sectional view of a process for mounting the logic die 140 on the first redistribution structure 120.

Referring to FIG. 16, the logic die 140 may be mounted on the first redistribution structure 120. The heat dissipating member 141 may be disposed on the logic die 140. In some example embodiments, the logic die 140 may be bonded to the first redistribution structure 120 by performing a flip chip bonding process. The logic die 140 may be bonded to the first bonding pads 127 of the first redistribution structure 120 by the connection members 130 so that the logic die 140 may be electrically connected to the first redistribution structure 120.

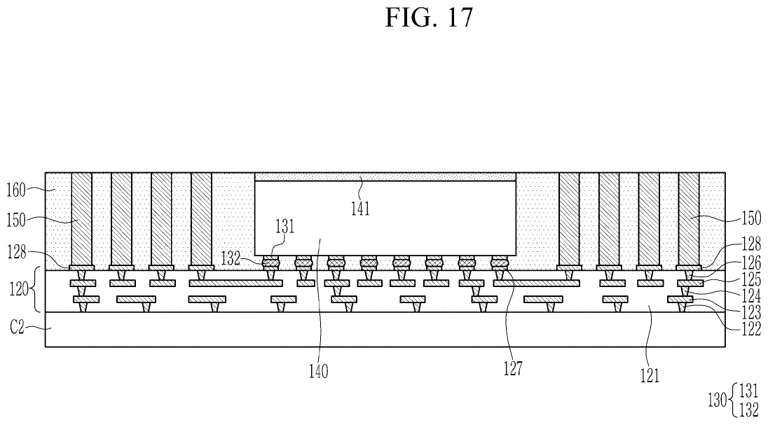

FIG. 17 shows a cross-sectional view of a process for molding the connection members 130, the logic die 140, and the conductive posts 150 on the first redistribution structure 120.

Referring to FIG. 17, the connection members 130, the logic die 140, and the conductive posts 150 may be covered by the first molding material 160 on the first redistribution structure 120. in some example embodiments, the molding process using the first molding material 160 may include the compression molding or the transfer molding process. In some example embodiments, the first molding material 160 may include the epoxy molding compound (EMC).

The chemical mechanical polishing (CMP) process may be performed to adjust the level of the upper surface of the first molding material 160, thereby planarizing the upper surface of the first molding material 160. When the chemical mechanical polishing (CMP) process is performed, the upper surface of the heat dissipating member 141 on the logic die 140 and the upper surfaces of the conductive posts 150 may be exposed.

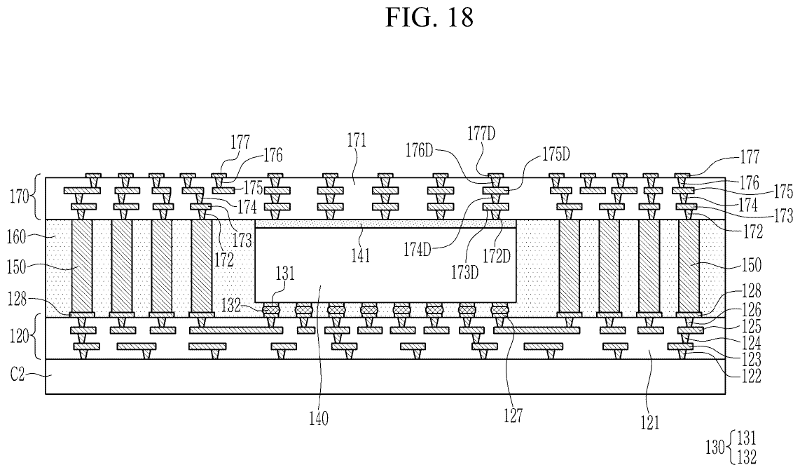

FIG. 18 shows a cross-sectional view of a process for forming a second redistribution structure 170 on the heat dissipating member 141, the conductive posts 150, and the first molding material 160.

Referring to FIG. 18, the second redistribution structure 170 may be formed on the heat dissipating member 141, the conductive posts 150, and the first molding material 160.

A second dielectric 171 may be formed as a film on the heat dissipating member 141, the conductive posts 150, and the first molding material 160, and the second dielectric 171 may be selectively etched to form openings, and the openings may be filled with a conductive material to thus sequentially form the fourth redistribution vias 172 and the first dummy redistribution vias 172D, the third redistribution lines 173 and the first dummy redistribution lines 173D, the fifth redistribution vias 174 and the second dummy redistribution vias 174D, the fourth redistribution lines 175 and the second dummy redistribution lines 175D, and the sixth redistribution vias 176 and the third dummy redistribution vias 176D. When the sixth redistribution vias 176 and the third dummy redistribution vias 176D are formed, the photoresist may be additionally deposited on the sixth redistribution vias 176 and the second dielectric 171, and the third dummy redistribution vias 176D and the second dielectric 171, and the photoresist may be selectively exposed and developed to form a photoresist pattern including openings, and the openings may be filled with the conductive material to form the third bonding pads 177 and the dummy bonding pads 177D.

In some example embodiments, the second dielectric 171 may be formed as a film by performing the spin coating process. In some example embodiments, the second dielectric 171 may include the photo imageable dielectric (PID) used in the redistribution layer process. In some example embodiments, the photo imageable dielectric (PID) may include polyimide-based photoactive polymer, novolak-based photoactive polymer, polybenzoxazole, silicon-based polymer, acrylate-based polymer, or epoxy-based polymer. In some example embodiments, as the photoresist process and the etching process are performed, the second dielectric 171 may be etched, and openings may be formed in the second dielectric 171. In some example embodiments, the fourth redistribution vias 172 and the first dummy redistribution vias 172D, the third redistribution lines 173 and the first dummy redistribution lines 173D, the fifth redistribution vias 174 and the second dummy redistribution vias 174D, the fourth redistribution lines 175 and the second dummy redistribution lines 175D, the sixth redistribution vias 176 and the third dummy redistribution vias 176D, and the third bonding pads 177 and the dummy bonding pads 177D may be formed by performing the sputtering process, or may be formed by forming a seed metal layer and performing the electrolytic plating process. In some example embodiments, the fourth redistribution vias 172 and the first dummy redistribution vias 172D, the third redistribution lines 173 and the first dummy redistribution lines 173D, the fifth redistribution vias 174 and the second dummy redistribution vias 174D, the fourth redistribution lines 175 and the second dummy redistribution lines 175D, the sixth redistribution vias 176 and the third dummy redistribution vias 176D, and the third bonding pads 177 and the dummy bonding pads 177D may respectively include at least one of copper, aluminum, tungsten, nickel, gold, tin, titanium, and alloys thereof.

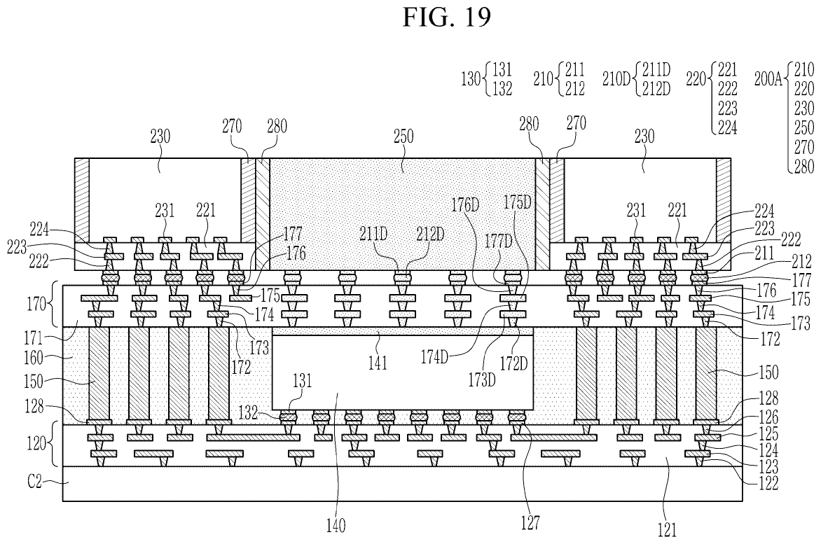

FIG. 19 shows a cross-sectional view of a process for mounting a memory package 200A on the second redistribution structure 170.

Referring to FIG. 19, the memory package 200A may be mounted on the second redistribution structure 170. In some example embodiments, the memory package 200A may be bonded to the second redistribution structure 170 by performing the flip chip bonding process. The memory package 200A may be bonded to the third bonding pads 177 of the second redistribution structure 170 by the first bumps 210 and may be bonded to the dummy bonding pads 177D of the second redistribution structure 170 by the second bumps 210D so the memory package 200A may be electrically and thermally connected to the second redistribution structure 170.

An integral memory package including the memory structures 230 and the heat dissipating structure 250 may be mounted on the second redistribution structure 170 of the package on package (PoP) by performing the flip chip process. As the memory package 200A is mounted on the second redistribution structure 170 by one bonding process, the time and/or cost for manufacturing the semiconductor package 100A may be reduced, compared to the case of respectively bonding the memory structures 230 and the heat dissipating structure 250 on the second redistribution structure 170.

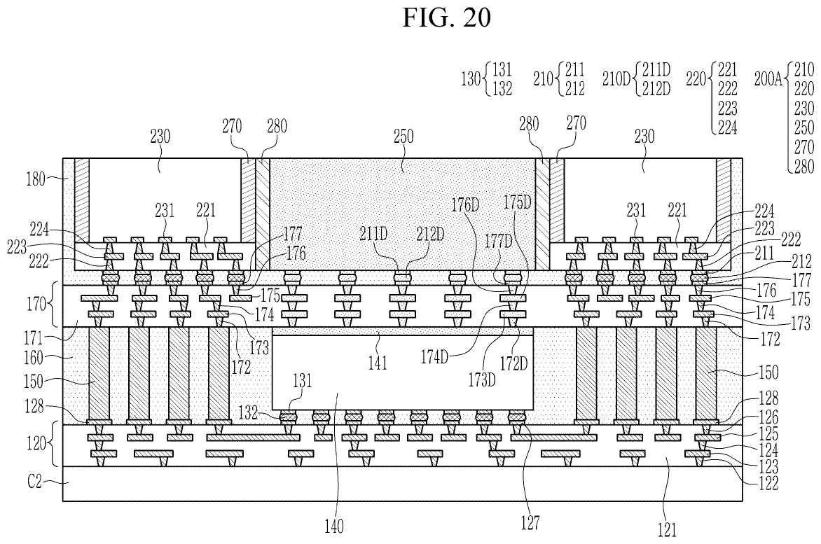

FIG. 20 shows a cross-sectional view of a process for molding the memory package 200A on the second redistribution structure 170.

Referring to FIG. 20, the memory package 200A may be covered by the second molding material 180 on the second redistribution structure 170. In some example embodiments, the molding process using the second molding material 180 may include the compression molding or the transfer molding process. In some example embodiments, the second molding material 180 may include the epoxy molding compound (EMC).

The chemical mechanical polishing (CMP) process may be performed to adjust the level of the upper surface of the second molding material 180, thereby planarizing the upper surface of the second molding material 180. When the chemical mechanical polishing (CMP) process is performed, the upper surfaces of the memory structures 230 and the upper surface of the heat dissipating structure 250 may be exposed.

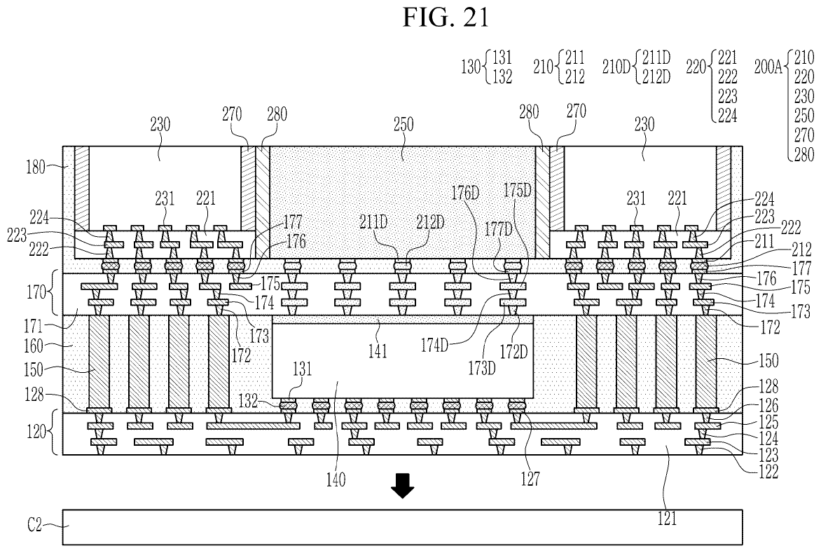

FIG. 21 shows a cross-sectional view of a process for removing the carrier C2 from the bottom surface of the first redistribution structure 120.

Referring to FIG. 21, the carrier C2 may be removed from the bottom surface of the first redistribution structure 120. As shown in FIG. 1, an external connection structure 110 may be formed on the bottom surface of the first redistribution structure 120. The conductive pads 111 may be formed below the first redistribution vias 122 of the first redistribution structure 120. In some example embodiments, the conductive pad 111 may include at least one of copper, nickel, zinc, gold, silver, platinum, palladium, chromium, titanium, and alloys thereof. In some example embodiments, the conductive pad 111 may be formed by performing the sputtering process, or may be formed by forming a seed metal layer and performing the electrolytic plating process. The external connection member 112 may be formed below the respective conductive pads 111. In some example embodiments, the external connection member 112 may include at least one of tin, silver, lead, nickel, copper, and alloys thereof.

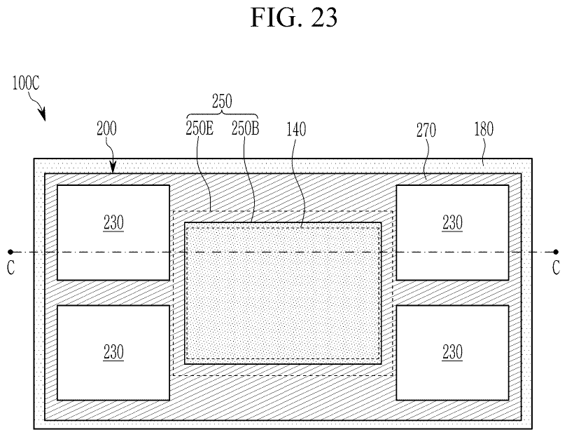

FIG. 22 shows a cross-sectional view of a semiconductor package 100C according to some example embodiments. FIG. 22 shows a cross-sectional view of a semiconductor package 100C with respect to a line C-C according to some example embodiments of FIG. 23.

Referring to FIG. 22, the semiconductor package 100C may include a memory package 200C. The memory package 200C may include first bumps 210, second bumps 210D, an interposer 220, memory structures 230, third bumps 240, a heat dissipating structure 250, an adhesive member 251, and a third molding material 270.

The interposer 220 may be disposed on the first bumps 210. The interposer 220 may include an interposer base 221, first vias 222, wiring lines 223, second vias 224, and bonding pads 225. The memory structures 230, the third bumps 240, the heat dissipating structure 250, and the third molding material 270 may be disposed on the upper surface of the interposer 220, and the interposer 220 may support the memory structures 230, the third bumps 240, the heat dissipating structure 250, and the third molding material 270. The interposer 220 may electrically connect the first bumps 210 and the third bumps 240. In some example embodiments, the interposer 220 may include a silicon interposer, a redistribution interposer, a glass interposer, and a composite interposer.

The interposer base 221 may protect and insulate the first vias 222, the wiring lines 223, and the second vias 224. The bonding pads 225 may be disposed on the interposer base 221. In some example embodiments, the interposer base 221 may include a photo imageable dielectric (PID). In some example embodiments, the interposer base 221 may include a silicon material or a glass material.

The first vias 222, the wiring lines 223, the second vias 224, and the bonding pads 225 may be sequentially disposed from the bottom, and may form signal, ground, and electric power routing paths. The wiring lines 223 may extend in the horizontal direction in the interposer base 221. The first vias 222 and the second vias 224 may extend in the vertical direction in the interposer base 221. The interposer 220 includes tow-layered vias in some example embodiments of FIG. 1, and in some example embodiments the interposer 220 may include a greater/lesser number of wire layers and vias. In some example embodiments, the first vias 222, the wiring lines 223, the second vias 224, and the bonding pads 225 may include at least one of copper, aluminum, silver, tin, gold, nickel, lead, titanium, and alloys thereof, respectively.

The memory structures 230 may be physically and electrically connected to the bonding pads 225 of the interposer 220 by the third bumps 240.

Each of the third bumps 240 may be disposed between the corresponding bonding pad 225 among the bonding pads 225 and the memory structure 230, and may electrically connect the memory structure 230 to the corresponding bonding pad 225. Each of the third bumps 240 may include a third pillar 241 and a third solder 242. The third pillar 241 may be disposed between the corresponding wire among the wires of the memory structure 230 and the corresponding third solder 242. The third pillar 241 may electrically connect the corresponding wire among the wires of the memory structure 230 to the corresponding first solder 212. In some example embodiments, the third pillar 241 may include at least one of copper, aluminum, silver, tin, gold, nickel, lead, titanium, and alloys thereof. The third solder 242 may be disposed between the corresponding third pillar 241 and the corresponding bonding pad 225 among the bonding pads 225. The third solder 242 may electrically connect the corresponding third pillar 241 to the corresponding bonding pad 225. In some example embodiments, the third solder 242 may include at least one of tin, silver, lead, nickel, copper, and alloys thereof.

The heat dissipating structure 250 may include a main body 250B and an extension part 250E. The main body 250B and the extension part 250E may be partitioned by dotted lines DL. The main body 250B may be disposed in the through opening TO of the interposer 220. The main body 250B may contact the interposer 220 in the through opening TO. The extension part 250E may extend in an external direction from an external circumferential surface of the main body 250B. The extension part 250E may be disposed around the through opening TO and on the upper surface of the interposer 220. The through opening TO may be covered (e.g., laterally surrounded) by the extension part 250E. The extension part 250E may extend in the horizontal direction from at least a portion of the external circumferential surface exposed to the outside of the through opening TO among the external circumferential surface of the main body 250B.

The adhesive member 251 may be disposed between the interposer 220 and the extension part 250E. The adhesive member 251 may attach the extension part 250E to the interposer 220. In some example embodiments, the adhesive member 251 may include a thermal interface material (TIM). The thermal interface material (TIM) may be inserted between the interposer 220 and the extension part 250E, and may increase a thermal combination between the interposer 220 and the extension part 250E. The thermal interface material (TIM) may fill an air layer of a contacting surface between the interposer 220 and the extension part 250E to reduce heat contact resistance.

The third molding material 270 may cover the memory structures 230 and the heat dissipating structure 250 on the interposer 220. The upper surface of the memory structure 230 and the upper surface of the heat dissipating structure 250 may be exposed from the third molding material 270, and may have the same level as the upper surface of the third molding material 270.

The content described with respect to the semiconductor package 100A in FIG. 1 may be applied to structure not herein described with respect to the semiconductor package 100C according to some example embodiments in FIG. 22.

FIG. 23 shows a top plan view of an upper surface of the semiconductor package 100C of FIG. 22. Referring to FIG. 23, the second molding material 180, the memory structures 230, the main body 250B of the heat dissipating structure 250, and the third molding material 270 are shown with solid lines, and the logic die 140 and the extension part 250E of the heat dissipating structure 250 are shown with dotted lines.

Referring to FIG. 23, the second molding material 180 may surround the memory package 200C. The memory package 200C may include memory structures 230, a heat dissipating structure 250, and a third molding material 270. The memory package 200C may have a symmetric structure. The memory structures 230 and the heat dissipating structure 250 may be disposed side by side. The heat dissipating structure 250 may be disposed between the memory structures 230. The third molding material 270 may surround the memory structures 230 and the heat dissipating structure 250. The extension part 250E of the heat dissipating structure 250 may conformally extend in the external direction along the external circumferential surface of the main body 250B.

The footprint of the heat dissipating structure 250 may overlap the footprint of the logic die 140. The footprint of the logic die 140 may be included in the footprint of the heat dissipating structure 250. Referring to FIG. 22 and FIG. 23, the footprint of the dummy wire patterns and the footprint of the dummy bonding pads 177D may overlap the footprint of the logic die 140. Heat generated by the logic die 140 may form a hot spot of the upper portion of the logic die 140, and the dummy wire patterns, the dummy bonding pads 177D, the second bumps 210D, and the heat dissipating structure 250 may be disposed on the hot spot of the upper portion of the logic die 140. Hence, the heat generated by the logic die 140 may pass through the dummy wire patterns, the dummy bonding pads 177D, the second bumps 210D, and the heat dissipating structure 250 and may be more efficiently discharged to the outside of the semiconductor package 100C.

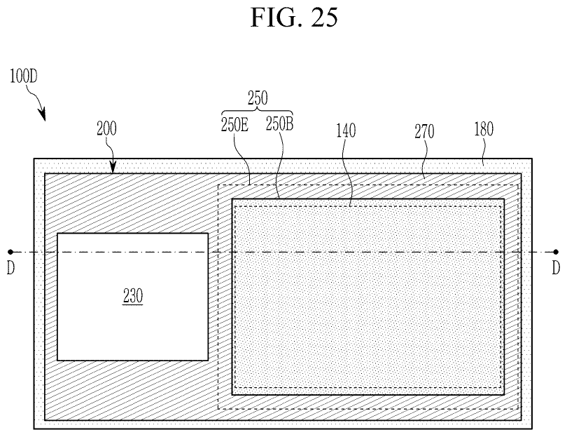

FIG. 24 shows a cross-sectional view of a semiconductor package 100D according to some example embodiments. FIG. 24 shows a cross-sectional view of a semiconductor package 100D with respect to a line D-D according to some example embodiments of FIG. 25. FIG. 25 shows a top plan view of an upper surface of a semiconductor package 100D of FIG. 24. Referring to FIG. 25, the second molding material 180, the memory structure 230, the main body 250B of the heat dissipating structure 250, and the third molding material 270 are shown with solid lines, and the logic die 140 and the extension part 250E of the heat dissipating structure 250 are shown with dotted lines.

Referring to FIG. 24 and FIG. 25, the semiconductor package 100D may include an asymmetric structure. The semiconductor package 100D may include conductive posts 150 disposed next to one lateral surface of the logic die 140. The semiconductor package 100D may include a memory structure 230 disposed next to one lateral surface of the heat dissipating structure 250. FIG. 25 shows one memory structure 230 disposed next to one lateral surface of the heat dissipating structure 250, and in some example embodiments the semiconductor package 100D may include the plurality of memory structures 230 disposed next to one lateral surface of the heat dissipating structure 250.

The content described with respect to the semiconductor package 100C in FIG. 22 and FIG. 23 may be applied to the structure not herein described with respect to the semiconductor package 100D according to some example embodiments in FIG. 24 and FIG. 25.

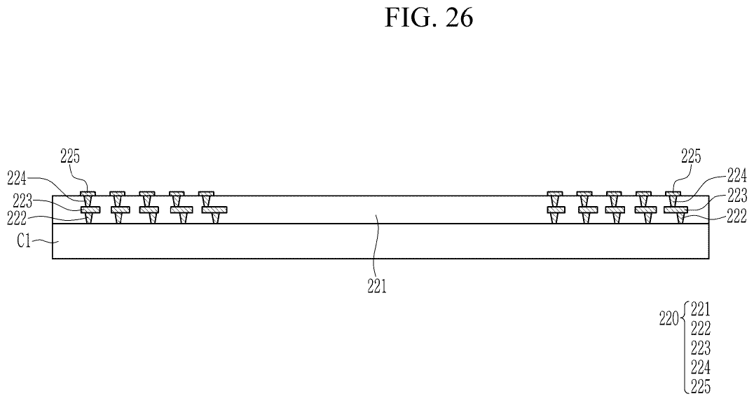

FIG. 26 to FIG. 34 show cross-sectional views of a method for manufacturing a memory package 200C according to some example embodiments of FIG. 22. FIG. 26 to FIG. 34 show cross-sectional views of a method for manufacturing a memory package 200C to which a chip last process is applied.

FIG. 26 shows a cross-sectional view on a process for forming an interposer 220 on the carrier C1. FIG. 26 shows some example embodiments in which the interposer 220 is a redistribution interposer 220. When the interposer 220 is a silicon interposer, a glass interposer, or a composite interposer, the interposer 220 manufactured in advance may be bonded on the memory structures 230.

Referring to FIG. 26, an interposer 220 may be formed on the carrier C1. A dielectric may be formed as a film on the carrier C1, the dielectric may be selectively etched to form openings, and the openings may be filled with a conductive material to sequentially form first vias 222, wiring lines 223, and second vias 224 from the bottom. As the first vias 222 and the second vias 224 are formed in advance by the chip last process, the first vias 222 and the second vias 224 may respectively have a shape of which a width in the horizontal direction increases when proceeding to the upper portion from the lower portion. Regarding the semiconductor package 100C that is the final product, the first vias 222 and the second vias 224 may respectively have a shape of which a width in the horizontal direction increases when proceeding to the upper portion from the lower portion. In some example embodiments, the dielectric may be formed into a film by performing the spin coating process. In some example embodiments, the dielectric may include the photo imageable dielectric (PID) used in the redistribution layer process. In some example embodiments, the photo imageable dielectric (PID) may include polyimide-based photoactive polymer, novolak-based photoactive polymer, polybenzoxazole, silicon-based polymer, acrylate-based polymer, or epoxy-based polymer. In some example embodiments, as the photoresist process and the etching process are performed on the dielectric, the dielectric may be etched, and openings may be formed in the dielectric. In some example embodiments, the first vias 222, the wiring lines 223, and the second vias 224 may be formed by performing the sputtering process, or may be formed by forming a seed metal layer and performing the electrolytic plating process. In some example embodiments, the first vias 222, the wiring lines 223, and the second vias 224 may respectively include at least one of copper, aluminum, tungsten, nickel, gold, tin, titanium, and alloys thereof.

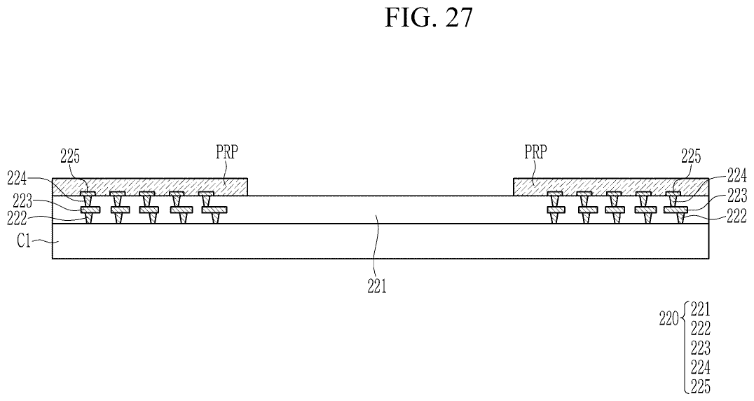

FIG. 27 shows a cross-sectional view of a process for forming a photoresist pattern PRP on the interposer base 221.

Referring to FIG. 27, photoresist may be formed as a film on the interposer base 221. In some example embodiments, the photoresist may be formed into a film by performing the spin coating process. In some example embodiments, the photoresist may include organic polymer resin including a photoactive material. The photoresist pattern PRP may be formed by exposing and developing the photoresist.

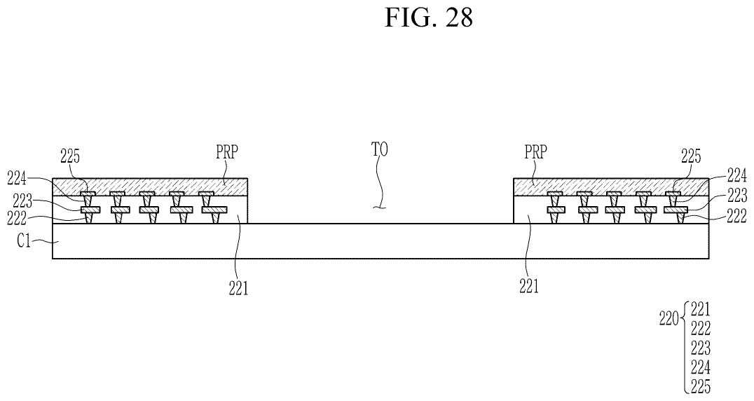

FIG. 28 shows a cross-sectional view of a process for forming a through opening TO in the interposer base 221.

Referring to FIG. 28, the through opening TO may be formed by etching the interposer base 221 exposed from the photoresist pattern PRP. The carrier C1 may be exposed through the through opening TO. In some example embodiments, the process for etching the interposer base 221 may be performed by a dry etching.

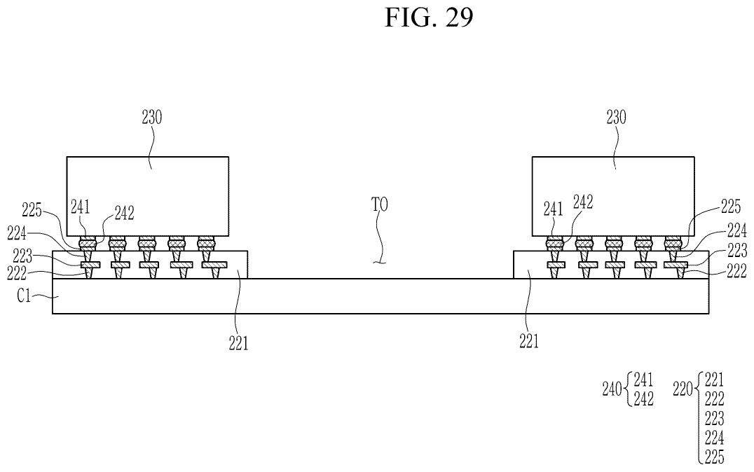

FIG. 29 shows a cross-sectional view of a process for mounting memory structures 230 on the interposer 220.

Referring to FIG. 29, the memory structures 230 may be mounted on the interposer 220. In some example embodiments, the memory structures 230 may be bonded on the interposer 220 by performing the flip chip bonding process. The memory structures 230 may be bonded to the bonding pads 225 of the interposer 220 by the third bumps 240 so that the memory structures 230 may be electrically connected to the interposer 220.

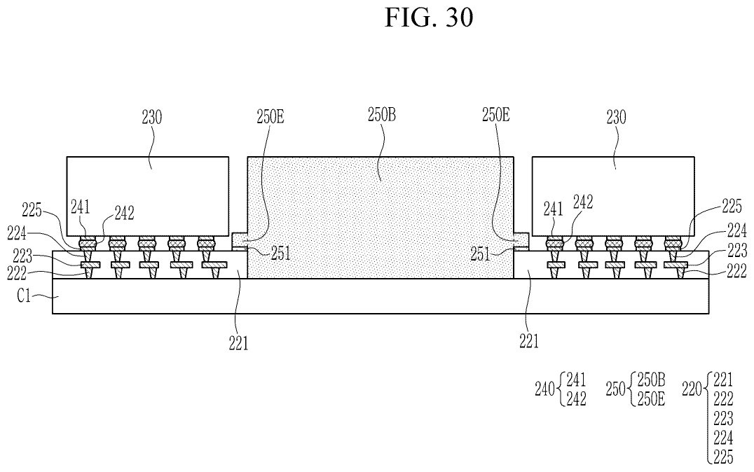

FIG. 30 shows a cross-sectional view of a process for attaching a heat dissipating structure 250 on the carrier C1, on the interposer 220, and in the through opening TO.

Referring to FIG. 30, the heat dissipating structure 250 may be attached on the carrier C1, on the interposer 220, and in the through opening TO In some example embodiments, the main body 250B of the heat dissipating structure 250 may be attached to the carrier C1 by a die attach film (not shown). In some example embodiments, the extension part 250E of the heat dissipating structure 250 may be attached on the interposer 220 by the adhesive member 251.

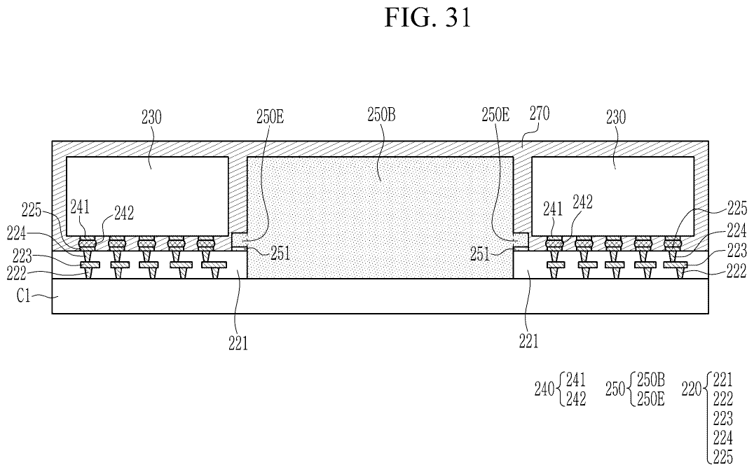

FIG. 31 shows a cross-sectional view of a process for molding the memory structures 230, the third bumps 240, and the heat dissipating structure 250 on the interposer 220.

Referring to FIG. 31, the memory structures 230, the third bumps 240, and the heat dissipating structure 250 may be covered with the third molding material 270 on the interposer 220. In some example embodiments, the molding process using the third molding material 270 may include the compression molding or the transfer molding process. In some example embodiments, the third molding material 270 may include the epoxy molding compound (EMC).

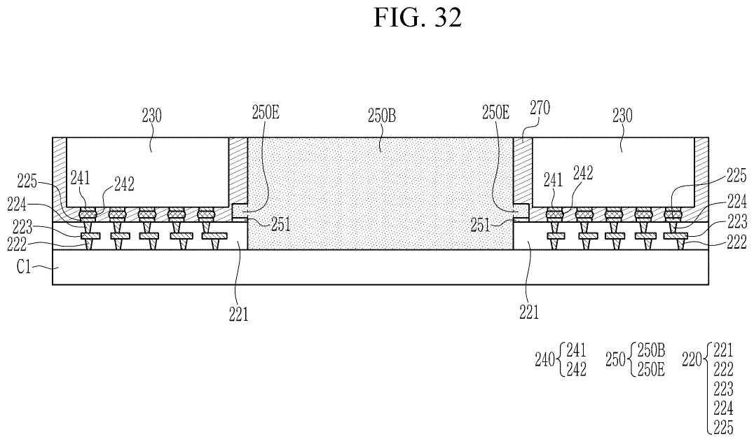

FIG. 32 shows a cross-sectional view of a process for performing a chemical mechanical polishing (CMP) process on the third molding material 270.

Referring to FIG. 32, the chemical mechanical polishing (CMP) process may be performed to adjust the level of the upper surface of the third molding material 270, thereby planarizing the upper surface of the third molding material 270. When the chemical mechanical polishing (CMP) process is performed, the upper surfaces of the memory structures 230 and the upper surface of the heat dissipating structure 250 may be exposed.

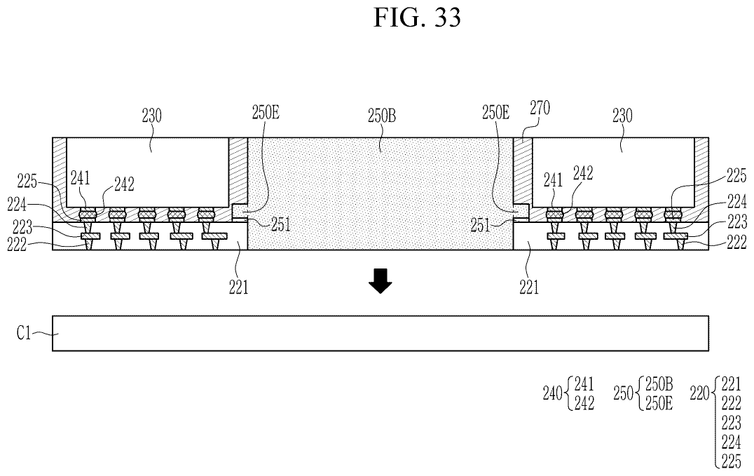

FIG. 33 shows a cross-sectional view of a process for removing the carrier C1 from the bottom surface of the interposer 220.

Referring to FIG. 33, the carrier C1 may be removed from the bottom surface of the interposer 220.

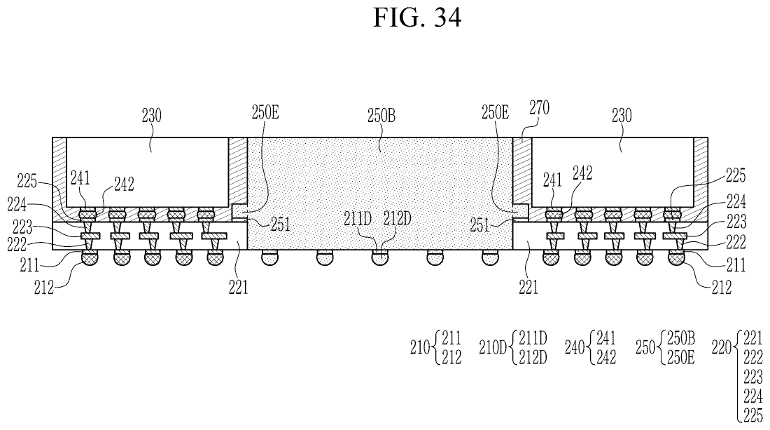

FIG. 34 shows a cross-sectional view of a process for forming first bumps 210 on the bottom surface of the interposer 220 and forming second bumps 210D on the bottom surface of the heat dissipating structure 250.

Referring to FIG. 34, first bumps 210 may be formed on the bottom surface of the interposer 220, and second bumps 210D may be formed on the bottom surface of the heat dissipating structure 250. A first pillar 211 may be formed on each of the first vias 222 of the interposer 220, and a second pillar 211D may be formed on the heat dissipating structure 250. In some example embodiments, the first pillar 211 and the second pillar 211D may respectively include at least one of copper, nickel, zinc, gold, silver, platinum, palladium, chromium, titanium, and alloys thereof. In some example embodiments, the first pillar 211 and the second pillar 211D may be formed by performing the sputtering process, or may be formed by forming a seed metal layer and performing the electrolytic plating process. A first solder 212 may be formed on the first pillar 211, and a second solder 212D may be formed on the second pillar 211D. In some example embodiments, the first solder 212 and the second solder 212D may respectively include at least one of tin, silver, lead, nickel, copper, and alloys thereof.

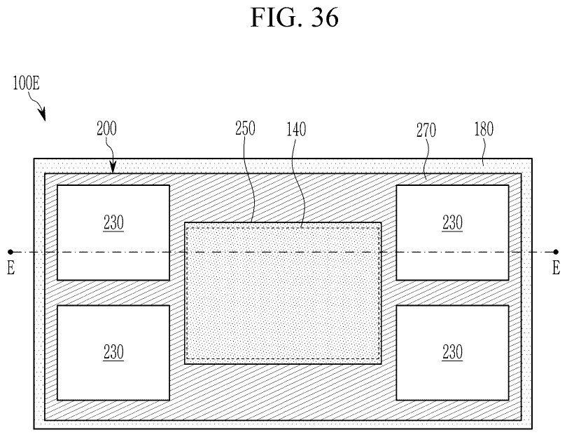

FIG. 35 shows a cross-sectional view of a semiconductor package 100E according to some example embodiments. FIG. 35 shows a cross-sectional view of a semiconductor package 100E with respect to a line E-E according to some example embodiments of FIG. 36.

Referring to FIG. 35, the semiconductor package 100E may include a memory package 200E. The memory package 200E may include first bumps 210, second bumps 210D, an interposer 220, memory structures 230, third bumps 240, a heat dissipating structure 250, fourth bumps 260, and a third molding material 270.

The interposer 220 may be disposed on the first bumps 210 and the second bumps 210D. The interposer 220 may include an interposer base 221, first vias 222, wiring lines 223, second vias 224, bonding pads 225, first dummy vias 222D, dummy lines 223D, second dummy vias 224D, and dummy bonding pads 225D. The memory structures 230, the third bumps 240, the heat dissipating structure 250, the fourth bumps 260, and the third molding material 270 may be disposed on the upper surface of the interposer 220, and the interposer 220 may support the memory structures 230, the third bumps 240, the heat dissipating structure 250, the fourth bumps 260, and the third molding material 270. The interposer 220 may electrically connect the first bumps 210 and the third bumps 240. The interposer 220 may thermally connect the second bumps 210D and the fourth bumps 260. In some example embodiments, the interposer 220 may include a silicon interposer, a redistribution interposer, a glass interposer, and a composite interposer.

The interposer base 221 may protect and insulate the first vias 222, the wiring lines 223, the second vias 224, the first dummy vias 222D, the dummy lines 223D, and the second dummy vias 224D. The bonding pads 225 and the dummy bonding pads 225D may be disposed on the interposer base 221. In some example embodiments, the interposer base 221 may include a photo imageable dielectric (PID). In some example embodiments, the interposer base 221 may include a silicon material or a glass material.

The first vias 222, the wiring lines 223, the second vias 224, and the bonding pads 225 may be sequentially disposed from the bottom, and may form signal, ground, and electric power routing paths. The first dummy vias 222D, the dummy lines 223D, the second dummy vias 224D, and the dummy bonding pads 225D may be sequentially disposed from the bottom, may be thermally connected to each other, and taken together may be characterized as a thermal conduction path. The wiring lines 223 and the dummy lines 223D may extend in the horizontal direction in the interposer base 221. The first vias 222, the second vias 224, the first dummy vias 222D, and the second dummy vias 224D may extend in the vertical direction in the interposer base 221. Example embodiments of FIG. 1 show that the interposer 220 includes the vias of two layers, and in some example embodiments the interposer 220 may include a greater/lesser number of wire layers and vias. In some example embodiments, the first vias 222, the wiring lines 223, the second vias 224, the bonding pads 225, the first dummy vias 222D, the dummy lines 223D, the second dummy vias 224D, and the dummy bonding pads 225D may respectively include at least one of copper, aluminum, silver, tin, gold, nickel, lead, titanium, and alloys thereof.

The memory structures 230 may be disposed on the interposer 220. The memory structures 230 may be physically and electrically connected to the bonding pads 225 of the interposer 220 by the third bumps 240.

The respective third bumps 240 may be disposed between the corresponding bonding pad 225 among the bonding pads 225 and the memory structure 230, and may electrically connect the memory structure 230 to the corresponding bonding pad 225. Each of the third bumps 240 may include a third pillar 241 and a third solder 242. The third pillar 241 may be disposed between the corresponding wire among the wires of the memory structure 230 and the corresponding third solder 242. The third pillar 241 may electrically connect the corresponding wire among the wires of the memory structure 230 to the corresponding third solder 242. In some example embodiments, the third pillar 241 may include at least one of copper, aluminum, silver, tin, gold, nickel, lead, titanium, and alloys thereof. The third solder 242 may be disposed between the corresponding third pillar 241 and the corresponding bonding pad 225 among the bonding pads 225. The third solder 242 may electrically connect the corresponding third pillar 241 to the corresponding bonding pad 225. In some example embodiments, the third solder 242 may include at least one of tin, silver, lead, nickel, copper, and alloys thereof.

The heat dissipating structure 250 may be disposed on the interposer 220. The heat dissipating structure 250 may be physically and thermally connected to the interposer 220 by the fourth bumps 260.

Each of the fourth bumps 260 may be disposed between the corresponding dummy bonding pad 225D among the dummy bonding pads 225D and the heat dissipating structure 250, and may thermally connect the heat dissipating structure 250 to the corresponding dummy bonding pad 225D. Each of the fourth bumps 260 may include a fourth pillar 261 and a fourth solder 262. The fourth pillar 261 may be disposed between the heat dissipating structure 250 and the corresponding fourth solder 262. The fourth pillar 261 may electrically connect the heat dissipating structure 250 to the corresponding fourth solder 262. In some example embodiments, the fourth pillar 261 may include at least one of copper, aluminum, silver, tin, gold, nickel, lead, titanium, and alloys thereof. The fourth solder 262 may be disposed between the corresponding fourth pillar 261 and the corresponding dummy bonding pad 225D among the dummy bonding pads 225D. The fourth solder 262 may thermally connect the corresponding fourth pillar 261 to the corresponding dummy bonding pad 225D. In some example embodiments, the fourth solder 262 may include at least one of tin, silver, lead, nickel, copper, and alloys thereof.

The third molding material 270 may cover the memory structures 230, the third bumps 240, the heat dissipating structure 250, and the fourth bumps 260 on the interposer 220. The upper surface of the memory structure 230 and the upper surface of the heat dissipating structure 250 may be exposed from the third molding material 270, and may have the same level as the upper surface of the third molding material 270.

The content described with respect to the semiconductor package 100A in FIG. 1 may be applied to structure not herein described with respect to the semiconductor package 100E according to some example embodiments in FIG. 35.

FIG. 36 shows a top plan view of an upper surface of a semiconductor package 100E of FIG. 35. Referring to FIG. 36, the second molding material 180, the memory structures 230, the heat dissipating structure 250, and the third molding material 270 are shown with solid lines, and the logic die 140 is shown with dotted lines.

Referring to FIG. 36, the second molding material 180 may surround the memory package 200E. The memory package 200E may include memory structures 230, a heat dissipating structure 250, and a third molding material 270. The memory package 200E may have a symmetric structure. The memory structures 230 and the heat dissipating structure 250 may be disposed side by side. The heat dissipating structure 250 may be disposed between the memory structures 230. The third molding material 270 may surround the memory structures 230 and the heat dissipating structure 250.

The footprint of the heat dissipating structure 250 may overlap the footprint of the logic die 140. The footprint of the logic die 140 may be included in the footprint of the heat dissipating structure 250. Referring to FIG. 35 and FIG. 36, the footprints of the dummy wire patterns, the dummy bonding pads 177D, the second bumps 210D, the first dummy vias 222D, the dummy lines 223D, the second dummy vias 224D, and the fourth bumps 260 may overlap the footprint of the logic die 140. Heat generated by the logic die 140 may form a hot spot at the upper portion of the logic die 140, and the dummy wire patterns, the dummy bonding pads 177D, the second bumps 210D, the first dummy vias 222D, the dummy lines 223D, the second dummy vias 224D, the fourth bumps 260, and the heat dissipating structure 250 may be disposed at the hot spot of the upper portion of the logic die 140. Hence, the heat generated by the logic die 140 may pass through the dummy wire patterns, the dummy bonding pads 177D, the second bumps 210D, the first dummy vias 222D, the dummy lines 223D, the second dummy vias 224D, the fourth bumps 260, and the heat dissipating structure 250, and may be more efficiently discharged to outside of the semiconductor package 100E.

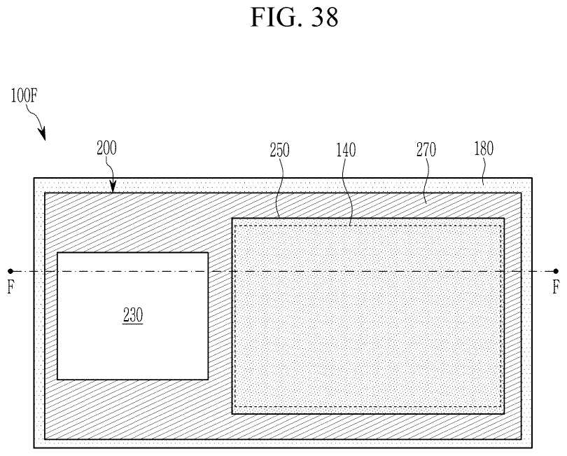

FIG. 37 shows a cross-sectional view of a semiconductor package 100F according to some example embodiments. FIG. 37 shows a cross-sectional view of a semiconductor package 100F with respect to a line F-F according to some example embodiments of FIG. 38. FIG. 38 shows a top plan view of an upper surface of a semiconductor package 100F of FIG. 37. Referring to FIG. 38, the second molding material 180, the memory structure 230, the heat dissipating structure 250, and the third molding material 270 are shown with solid lines, and the logic die 140 are shown with dotted lines.

Referring to FIG. 37 and FIG. 38, the semiconductor package 100F may include an asymmetric structure. The semiconductor package 100F may include conductive posts 150 disposed next to one lateral surface of the logic die 140. The semiconductor package 100F may include a memory structure 230 disposed next to one lateral surface of the heat dissipating structure 250. FIG. 38 shows one memory structure 230 disposed next to one lateral surface of the heat dissipating structure 250, and in some example embodiments the semiconductor package 100F may include a plurality of the memory structures 230 disposed next to one lateral surface of the heat dissipating structure 250.

The content described with respect to the semiconductor package 100E in FIG. 35 and FIG. 36 may be applied to structure not herein described with respect to the semiconductor package 100F according to some example embodiments in FIG. 37 and FIG. 38.

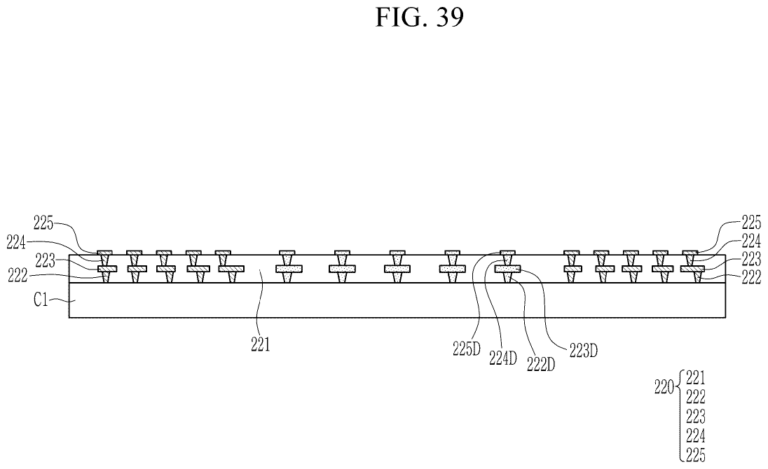

FIG. 39 to FIG. 45 show cross-sectional views of a method for manufacturing a memory package 200E according to some example embodiments of FIG. 35. FIG. 39 to FIG. 45 show cross-sectional views of a method for manufacturing a memory package 200E to which a chip last process is applied.

FIG. 39 shows a cross-sectional view of a process for forming an interposer 220 on the carrier C1. FIG. 39 shows some example embodiments in which the interposer 220 is a redistribution interposer 220. When the interposer 220 is a silicon interposer, a glass interposer, or a composite interposer, the interposer 220 manufactured in advance may be bonded to the memory structures 230.

Referring to FIG. 39, an interposer 220 may be formed on the carrier C1. A dielectric may be formed as a film on the carrier C1, the dielectric may be selectively etched to form openings, and the openings may be filled with a conductive material so that the first vias 222 and the first dummy vias 222D, the wiring lines 223 and the dummy lines 223D, and the second vias 224 and the second dummy vias 224D may be sequentially formed. As the first vias 222, the first dummy vias 222D, the second vias 224, and the second dummy vias 224D are formed in advance by the chip last process, the first vias 222, the first dummy vias 222D, the second vias 224, and the second dummy vias 224D may respectively have a shape of which a width in the horizontal direction increases when proceeding to the upper portion from the lower portion. Regarding the semiconductor package 100E that is the final product, the first vias 222, the first dummy vias 222D, the second vias 224, and the second dummy vias 224D may respectively have a shape of which a width in the horizontal direction increases when proceeding to the upper portion from the lower portion. In some example embodiments, the dielectric may be formed into a film by performing the spin coating process. In some example embodiments, the dielectric may include the photo imageable dielectric (PID) used in the redistribution layer process. In some example embodiments, the photo imageable dielectric (PID) may include polyimide-based photoactive polymer, novolak-based photoactive polymer, polybenzoxazole, silicon-based polymer, acrylate-based polymer, or epoxy-based polymer. In some example embodiments, as the photoresist process and the etching process are performed on the dielectric, the dielectric may be etched, and openings may be formed in the dielectric. In some example embodiments, the first vias 222 and the first dummy vias 222D, the wiring lines 223 and the dummy lines 223D, and the second vias 224 and the second dummy vias 224D may be formed by performing the sputtering process, or may be formed by forming a seed metal layer and performing the electrolytic plating process. In some example embodiments, the first vias 222 and the first dummy vias 222D, the wiring lines 223 and the dummy lines 223D, and the second vias 224 and the second dummy vias 224D may respectively include at least one of copper, aluminum, tungsten, nickel, gold, tin, titanium, and alloys thereof.

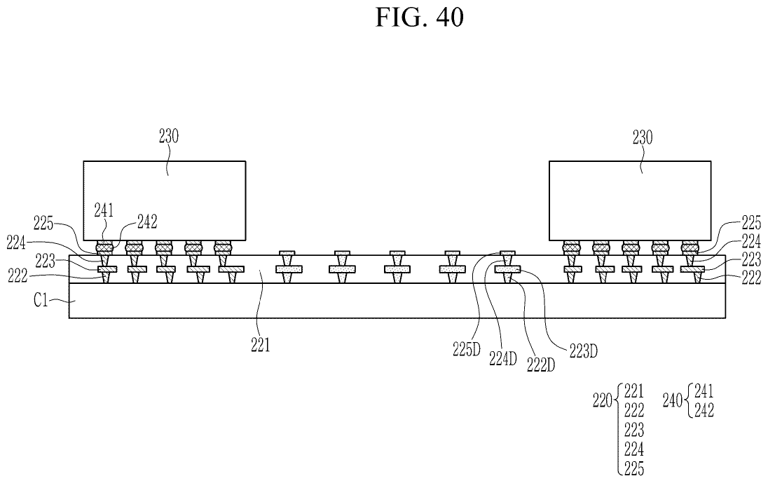

FIG. 40 shows a cross-sectional view of a process for mounting memory structures 230 on the interposer 220.

Referring to FIG. 40, the memory structures 230 may be mounted on the interposer 220. In some example embodiments, the memory structures 230 may be bonded to the interposer 220 by performing the flip chip bonding process. The memory structures 230 may be bonded to the bonding pads 225 of the interposer 220 by the third bumps 240 so that the, memory structures 230 may be electrically connected to the interposer 220.

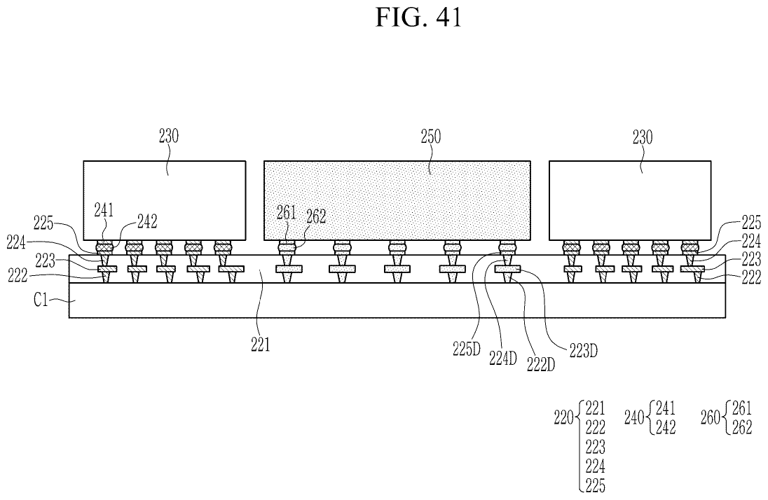

FIG. 41 shows a cross-sectional view on a process for mounting a heat dissipating structure 250 on the interposer 220.

Referring to FIG. 41, the heat dissipating structure 250 may be mounted on the interposer 220. In some example embodiments, the heat dissipating structure 250 may be bonded on the interposer 220 by performing the flip chip bonding process. The heat dissipating structure 250 may be bonded to the dummy bonding pads 225D of the interposer 220 by the fourth bumps 260 so that the heat dissipating structure 250 may be thermally connected to the dummy bonding pads 225D.

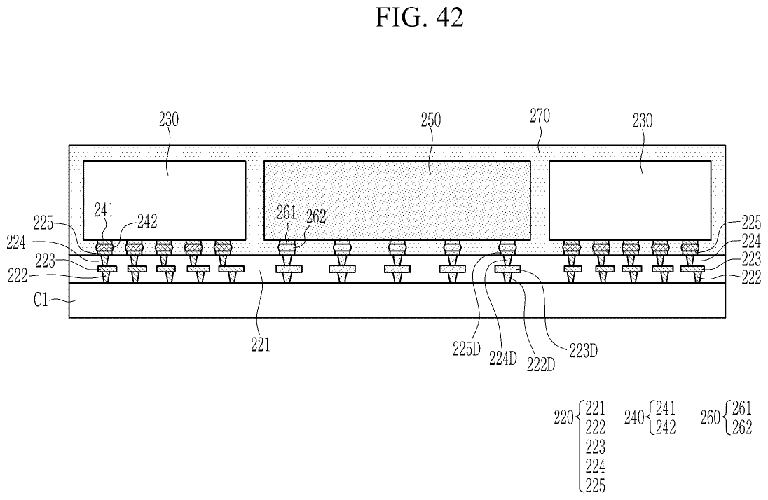

FIG. 42 shows a cross-sectional view of a process for molding memory structures 230, third bumps 240, a heat dissipating structure 250, and fourth bumps 260 on the interposer 220.

Referring to FIG. 42, the memory structures 230, the third bumps 240, the heat dissipating structure 250, and the fourth bumps 260 may be covered with the third molding material 270 on the interposer 220. In some example embodiments, the molding process using the third molding material 270 may include the compression molding or the transfer molding process. In some example embodiments, the third molding material 270 may include the epoxy molding compound (EMC).

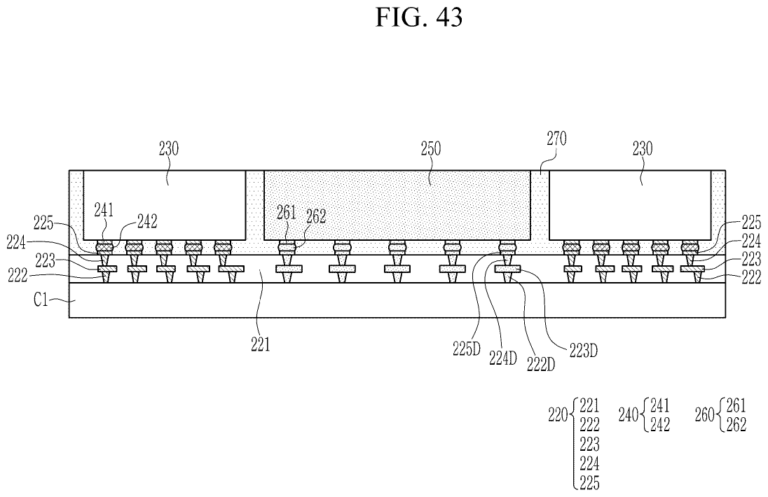

FIG. 43 shows a cross-sectional view of a process for performing a chemical mechanical polishing (CMP) process on the third molding material 270.

Referring to FIG. 43, the chemical mechanical polishing (CMP) process may be performed to adjust the level of the upper surface of the third molding material 270, thereby planarizing the upper surface of the third molding material 270. When the chemical mechanical polishing (CMP) process is performed, the upper surfaces of the memory structures 230 and the upper surface of the heat dissipating structure 250 may be exposed.

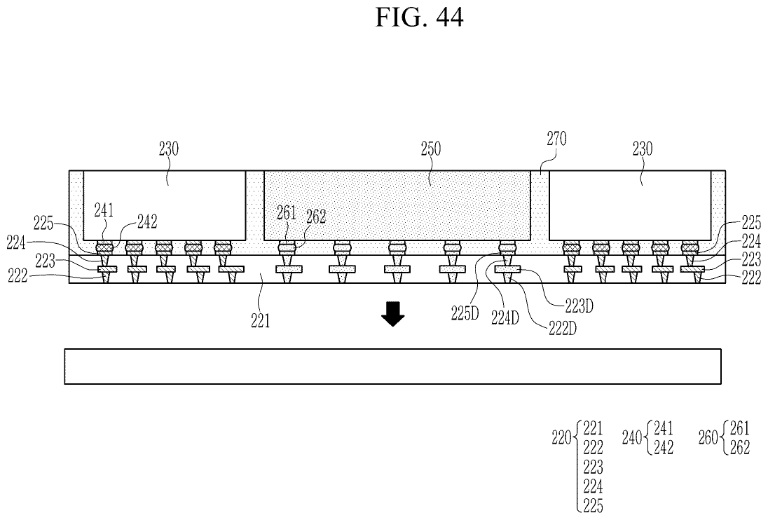

FIG. 44 shows a cross-sectional view of a process for removing the carrier C1 from the bottom surface of the interposer 220.

Referring to FIG. 44, the carrier C1 may be removed from the bottom surface of the interposer 220.

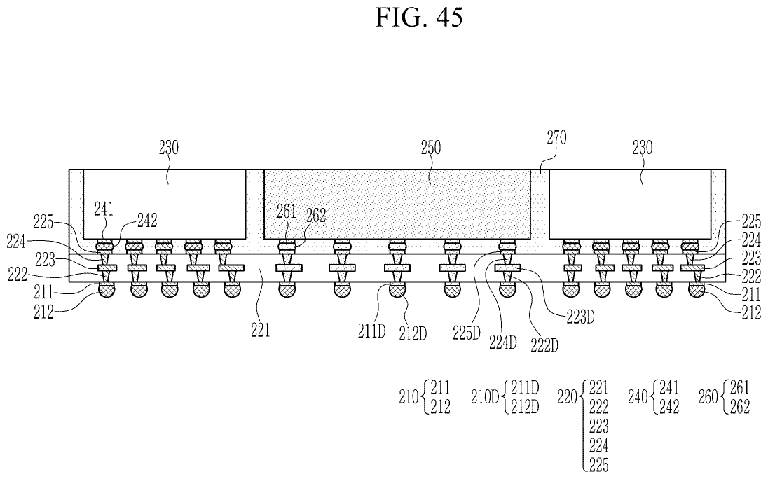

FIG. 45 shows a cross-sectional view of a process for forming first bumps 210 on the bottom surface of the interposer 220, and forming second bumps 210D on the bottom surface of the heat dissipating structure 250.

Referring to FIG. 45, first bumps 210 may be formed on the bottom surface of the interposer 220, and second bumps 210D may be formed on the bottom surface of the heat dissipating structure 250. A first pillar 211 may be formed on each of the first vias 222 of the interposer 220, and a second pillar 211D may be formed on the heat dissipating structure 250. In some example embodiments, the first pillar 211 and the second pillar 211D may respectively include at least one of copper, nickel, zinc, gold, silver, platinum, palladium, chromium, titanium, and alloys thereof. In some example embodiments, the first pillar 211 and the second pillar 211D may be respectively formed by performing the sputtering process, or may be formed by forming a seed metal layer and performing the electrolytic plating process. A first solder 212 may be formed on the first pillar 211, and a second solder 212D may be formed on the second pillar 211D. In some example embodiments, the first solder 212 and the second solder 212D may respectively include at least one of tin, silver, lead, nickel, copper, and alloys thereof.

While this disclosure has been described in connection with some example embodiments, it is to be understood that the disclosure is not limited to the disclosed some example embodiments, but, on the contrary, is intended to cover various modifications and variations included within the spirit and scope of the appended claims.

What is claimed is:

1. A semiconductor package comprising:
a first redistribution structure;
a logic die on the first redistribution structure;
a plurality of conductive posts on the first redistribution structure, the plurality of conductive posts being laterally next to the logic die;
a second redistribution structure on the logic die and the plurality of conductive posts; and
a memory package on the second redistribution structure,
wherein the memory package includes
a plurality of first bumps,
a plurality of second bumps laterally next to the plurality of first bumps,
an interposer on the plurality of first bumps, the interposer defining a through opening through the interposer,
a heat dissipating structure on the plurality of second bumps, the heat dissipating structure being in the through opening, and
a memory structure on the interposer, the memory structure being laterally next to the heat dissipating structure.

2. The semiconductor package of claim 1, wherein
the plurality of second bumps are dummy bumps.

3. The semiconductor package of claim 1, wherein
the plurality of second bumps are electrically disconnected from the second redistribution structure.

4. The semiconductor package of claim 1, wherein
the plurality of second bumps are thermally connected to the heat dissipating structure and the second redistribution structure.

5. The semiconductor package of claim 1, wherein the heat dissipating structure includes:
a main body; and
an extension part extending from an external circumferential surface of the main body, the extension part being around the through opening and on an upper surface of the interposer.

6. The semiconductor package of claim 5, wherein
the extension part laterally surrounds the through opening.

7. The semiconductor package of claim 5, wherein
the memory package further includes an adhesive member between the interposer and the extension part.

8. The semiconductor package of claim 1, wherein
the memory structure contacts the interposer.

9. The semiconductor package of claim 1, wherein
the memory package further includes a plurality of third bumps between the memory structure and the interposer.

10. A semiconductor package comprising:
a first redistribution structure;
a logic die on the first redistribution structure;
a plurality of conductive posts on the first redistribution structure, the plurality of conductive posts being laterally next to the logic die;
a second redistribution structure on the logic die and the plurality of conductive posts; and
a memory package on the second redistribution structure,
wherein the memory package includes
a plurality of bumps,
an interposer on the plurality of bumps,
a heat dissipating structure on the interposer, and
a memory structure on the interposer, the memory structure being laterally next to the heat dissipating structure.

11. The semiconductor package of claim 10, wherein
a footprint of the heat dissipating structure overlaps a footprint of the logic die.

12. The semiconductor package of claim 10, wherein
the memory structure comprises a plurality of memory structures, and
the heat dissipating structure is between the plurality of memory structures.

13. The semiconductor package of claim 10, wherein
the memory structure includes a DRAM or a high bandwidth memory (HBM).

14. A semiconductor package comprising:
a front-side redistribution structure;
a logic die on the front-side redistribution structure;
conductive posts on the front-side redistribution structure, the conductive posts being laterally next to the logic die;
a first molding material covering the logic die and the conductive posts on the front-side redistribution structure;
a back-side redistribution structure on the conductive posts and the first molding material;
a memory package on the back-side redistribution structure; and
a second molding material covering the memory package on the back-side redistribution structure,
wherein the memory package includes
an interposer defining a through opening through the interposer,
a plurality of first bumps between the back-side redistribution structure and the interposer,
a heat dissipating structure in the through opening,
a plurality of second bumps between the back-side redistribution structure and the heat dissipating structure,
a memory structure on the interposer, the memory structure being laterally next to the heat dissipating structure, and
a third molding material covering the memory structure on the interposer.

15. The semiconductor package of claim 14, wherein
the memory package further includes a fourth molding material in the through opening,
the fourth molding material being between the interposer and the heat dissipating structure, and between the third molding material and the heat dissipating structure.

16. The semiconductor package of claim 14, wherein
the third molding material includes a high dielectric constant molding material.

17. The semiconductor package of claim 14, wherein the back-side redistribution structure includes:
a dielectric;
a plurality of wire patterns in the dielectric;
a plurality of dummy wire patterns in the dielectric;
a plurality of bonding pads on the dielectric; and
a plurality of dummy bonding pads on the dielectric, the plurality of dummy bonding pads being laterally next to the plurality of bonding pads.

18. The semiconductor package of claim 17, wherein
the plurality of second bumps respectively contact corresponding dummy bonding pads among the plurality of dummy bonding pads.

19. The semiconductor package of claim 17, wherein
the plurality of dummy wire patterns and the plurality of dummy bonding pads are thermally connected to the plurality of second bumps and the heat dissipating structure.

20. The semiconductor package of claim 17, wherein
a footprint of the plurality of dummy wire patterns and the plurality of dummy bonding pads overlaps a footprint of the logic die.
